(19) United States
(12) Patent Application Publication
(10) Pub. No.: US 2024/0059572 A1
(43) Pub. Date: Feb. 22, 2024

(54) BOROPHANE POLYMORPHS AND SYNTHESIS METHODS OF SAME

(71) Applicant: NORTHWESTERN UNIVERSITY, Evanston, IL (US)

(72) Inventors: Mark C. Hersam, Wilmette, IL (US); Qiucheng Li, Evanston, IL (US)

(21) Appl. No.: 18/270,903

(22) PCT Filed: Jan. 12, 2022
(86) PCT No.: PCT/US2022/012082

§ 371 Date: Jul. 5, 2023

Related U.S. Application Data
(60) Provisional application No. 63/139,382, filed on Jan. 20, 2021.

(51) Int. Cl. C01B 35/02

(52) U.S. Cl. CPC C01B 35/026; C01P 2002/20; C01P 2006/80

(57) ABSTRACT

One aspect of this invention relates to synthesis of borophane polymorphs by hydrogenating borophene with atomic hydrogen in ultrahigh vacuum, including growing borophene on a substrate in an ultrahigh vacuum chamber; and performing hydrogenation of the borophene in situ to obtain borophane having a diverse set of borophane polymorphs. The borophane polymorphs are metallic with modified local work functions that can be reversibly returned to pristine borophene via thermal desorption of hydrogen. Hydrogenation also provides chemical passivation such that the borophane polymorphs have negligible oxidation for multiple days following ambient exposure.

### CROSS-REFERENCE TO RELATED PATENT APPLICATION

This application claims priority to and the benefit of U.S. Provisional Application No. 63/139,382, filed Jan. 20, 2021, which is incorporated herein in its entirety by reference.

### STATEMENT AS TO RIGHTS UNDER FEDERALLY-SPONSORED RESEARCH

This invention was made with government support under 1720139 awarded by the National Science Foundation, and N00014-17-1-2993 awarded by the Office of Naval Research. The government has certain rights in the invention.

### FIELD OF THE INVENTION

The present invention relates generally to the material science, and more particularly to borophane polymorphs and synthesis methods of same.

### BACKGROUND OF THE INVENTION

The background description provided herein is for the purpose of generally presenting the context of the invention. The subject matter discussed in the background of the invention section should not be assumed to be prior art merely as a result of its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the invention.

Since its initial experimental realization, studies of borophene have focused on its diverse polymorphism and predicted properties that include two-dimensional (2D) anisotropic metallicity, high mechanical strength and flexibility, and phonon-mediated superconductivity. However, borophene rapidly oxidizes in air, which has confined experimental characterization to ultrahigh vacuum (UHV) conditions and also posed challenges to integrating borophene into practical devices. Chemical passivation can suppress ambient oxidation for electronic materials. For example, monohydride termination of the dangling bonds on silicon surfaces minimizes native oxide formation. Similarly, covalent modification of 2D black phosphorus improves morphological stability and preserves electronic properties in ambient conditions. First principles calculations have suggested that borophene can also be stabilized through surface hydrogenation.

Beyond passivation, chemical functionalization can modulate the electronic properties of 2D materials. For instance, converting the carbon bonding configuration from sp² in graphene to sp³, hydrogenated graphene (i.e., ‘graphane’) leads to a tunable bandgap based on the hydrogen surface concentration. Drawing inspiration from graphane, hydrogenated borophene (i.e., ‘borophane’) has been explored theoretically. Predicted electronic properties include metallic, semiconducting, and Dirac characteristics with ultrahigh Fermi velocity and thermal conductance. Although hydrogen boride nanosheets have been reported based on chemical reactions involving inorganic salts, atomically well-defined synthesis and characterization of borophane polymorphs have not yet been achieved.

Therefore, a heretofore unaddressed need exists in the art to address the aforementioned deficiencies and inadequacies.

### SUMMARY OF THE INVENTION

In one aspect, the invention relates to a method of synthesizing borophane polymorphs. The method in one embodiment comprises growing borophene on a substrate in an ultrahigh vacuum (UHV) chamber; and performing hydrogenation of the borophene in situ to obtain a diverse set of borophane polymorphs.

In one embodiment, the UHV chamber has a base pressure of about 1.0×10⁻¹⁰ mbar during the borophene growth.

In one embodiment, the substrate comprises a substrate having a metal film formed of Ag, Au, Cu, Al, or Ir.

In one embodiment, the substrate comprises an atomically clean Ag(111) substrate having about 480-720 nm thick Ag(111) on a mica substrate.

In one embodiment, the substrate is obtained by cleaning the Ag(111) substrate via repeated cycles of Ar⁺ sputtering followed by annealing at about 450-550° C.

In one embodiment, said growing the borophene on the substrate comprises depositing boron on the substrate at a substrate temperature.

In one embodiment, said depositing the boron is performed by electron-beam evaporation of a solid boron rod, or high temperature effusion of the solid boron rod in a high temperature effusion cell.

In one embodiment, the solid boron rod has a purity of about 99.999-99.99999% boron.

In one embodiment, the borophene grown on the substrate has a dominant borophene polymorph determined by the substrate temperature.

In one embodiment, the substrate temperature is at about 320-660° C. during boron deposition.

In one embodiment, said hydrogenation is performed in situ by exposing the borophene to atomic hydrogen.

In one embodiment, the atomic hydrogen is generated by dissociation of the molecular hydrogen with a tungsten filament, or a platinum filament, or an iridium filament, or platinum/iridium filament, or by a hydrogen atom beam source that thermally crack molecular hydrogen into atomic hydrogen.

In one embodiment, during hydrogenation, the borophene is maintained at room temperature and directly faced the tungsten filament with a distance of about 8-12 cm.

In one embodiment, the chamber pressure during hydrogenation is maintained at about 1.0×10⁻⁷-5.0×10⁻⁶ mbar for about 1-20 min.

In another aspect of the invention, the method of synthesizing borophane polymorphs, comprises hydrogenating borophene with atomic hydrogen in ultrahigh vacuum (UHV).

In one embodiment, the borophene is grown on a substrate in the UHV by elemental boron evaporation.

In one embodiment, the substrate comprises a substrate having a metal film formed of Ag, Au, Cu, Al, or Ir.

In one embodiment, the borophene grown on the substrate has a dominant borophene polymorph determined by a substrate temperature of the substrate.

In one embodiment, the substrate temperature is at about 320-660° C. during boron deposition.

In one embodiment, said hydrogenating the borophene is performed by exposing borophene to atomic hydrogen.

In one embodiment, the atomic hydrogen is generated by dissociation of molecular hydrogen with a tungsten filament, or a platinum filament, or an iridium filament, or platinum/iridium filament, or by a hydrogen atom beam source that thermally crack molecular hydrogen into atomic hydrogen.

In yet another aspect, the invention relates to borophane polymorphs being synthesized according to the above disclosed method.

In one embodiment, the borophane polymorphs comprises at least eight borophane polymorphs.

In a further aspect, the invention relates to borophane comprising hydrogenated borophene having a diverse set of borophane polymorphs.

In one embodiment, the diverse set of borophane polymorphs comprises v_{1/5} borophane with square H and honeycomb H patterns, v_{1/5}-30° borophane with staggered rectangular H and zigzag H patterns, v_{1/6} borophane with hexagonal H and disordered rectangular H patterns, and v_{1/6}-30° borophane with hexagonal H and rectangular H patterns, wherein H represents hydrogen atoms.

In one embodiment, the v_{1/6}-30° borophane with the rectangular H pattern (rect-v_{1/6}-30° borophane) includes two-center-two-electron (2c2e) boron-hydrogen (B—H) bonds and three-center-two-electron (3c2e) boron-hydrogen-boron (B—H—B) bonds.

In one embodiment, the rect-v_{1/6}-30° borophane has a lower work function than v_{1/6}-30° borophene.

In one embodiment, the borophane polymorphs have tunable stoichiometric ratios of boron and hydrogen.

In one embodiment, the borophane polymorphs have negligible oxidation for multiple days following ambient exposure.

In one embodiment, the borophane polymorphs are metallic with modified local work functions compared to pristine borophene.

In one embodiment, the borophane polymorphs can be reversibly returned to pristine borophene via thermal desorption of hydrogen.

These and other aspects of the present invention will become apparent from the following description of the preferred embodiment taken in conjunction with the following drawings, although variations and modifications therein may be affected without departing from the spirit and scope of the novel concepts of the invention.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 shows atomic characterization of borophane polymorphs according to embodiments of the invention. Panel A: Representative STM image of v_{1/5} borophane with square H and honeycomb H patterns. Panel B: STM image of square v_{1/5} borophane (inset: FFT). Panel C: STM image of honeycomb v_{1/5} borophane (inset: FFT). Panel D: Representative STM image of v_{1/5}-30° borophane showing intermixing of staggered rectangular H and zigzag H patterns. Panel E: STM image of staggered rectangular v_{1/5}-30° borophane (inset: FFT). Panel F: STM image of intermixed zigzag v_{1/5}-30° borophane (inset: FFT). Panel G: Representative STM image of v_{1/6} borophane with hexagonal H and disordered rectangular H patterns. Panel H: STM image of hexagonal v_{1/6} borophane (inset: FFT). Panel I: STM image of disordered rectangular v_{1/6} borophane (inset: FFT). Panel J: Representative v_{1/6}-30° borophane with hexagonal H and rectangular H patterns. A line defect of v_{1/5}-30° borophane is also present (marked with a green arrow). Panel K: STM image of hexagonal v_{1/6}-30° borophane (inset: FFT). Panel L: STM image of rectangular v_{1/6}-30° borophane (inset: FFT). All STM images are characterized with a CO-functionalized Pt/Ir tip. All scale bars for the FFT images are 2 nm⁻¹. Yellow polygons indicate the unit cells of borophane polymorphs; yellow dots indicate the protrusions of H adatoms in STM images. Scanning conditions: (panel A) V_{S}=60 mV, I_{T}=200 pA; (panel B) V_{S}=20 mV, I_{T}=60 pA; (panel C) V_{S}=60 mV, I_{T}=200 pA; (panel D) V_{S}=60 mV, I_{T}=300 pA; (panel E) V_{S}=100 mV, I_{T}=50 pA; (panel F) V_{S}=30 mV, I_{T}=500 pA; (panel G) V_{S}=8 mV, I_{T}=100 pA; (panel H) V_{S}=10 mV, I_{T}=100 pA; (panel I) V_{S}=2 mV, I_{T}=100 pA; (panel J) V_{S}=100 mV, I_{T}=50 pA; (panel K) V_{S}=100 mV, I_{T}=50 pA; (panel L) V_{S}=20 mV, I_{T}=50 pA. Hydrogen dosing conditions are as follows: [(panel A) and (panel C)]5.0×10⁻⁷ mbar for 20 min; (panel B) 1.0×10⁻⁶ mbar for 10 min; [(panel D) and (panel F)] 5.0×10⁻⁶ mbar for 2 min; (panel E) 2.5×10⁻⁶ mbar for 10 min; [(panel G) to (panel I)]1.0×10⁻⁶ mbar for 10 min; [(panel J) to (panel L)]2.5×10⁻⁶ mbar for 10 min.

FIG. 2 shows Rect-v_{1/6}-30° borophane structure and electronic properties according to embodiments of the invention. Panels A-B: CO-STM images of rect-v_{1/6}-30° borophane with overlaid unit cell of 0.50 nm by 0.30 nm at different bias (scanning conditions: (panel A) V_{S}=100 mV, I_{T}=100 pA; (panel B) V_{S}=24 mV, I_{T}=80 pA). Panels C and F: Side (panel C) and top (panel F) views of the rect-1Hₜₒₚ structure with 1 Hₜₒₚ atom in the rectangular unit cell. Panels D and G: Side (panel D) and top (panel G) views of the rect-1H_{bridge} structure with 1 H_{bridge} atom in the rectangular unit cell. Panels E and H: Side (panel E) and top (panel H) views of the rect-2H structure with 1 Hₜₒₚ atom and 1 H_{bridge} atom in the rectangular unit cell. Panels I-K: Simulated density of states with the energy range of 100 meV above the Fermi level of rect-1Hₜₒₚ (panel I), rect-1H_{bridge} (panel J) and rect-2H (panel K) structures. Panel L: STS spectra taken on rect-v_{1/6}-30° borophane (red) and v_{1/6}-30° borophene (purple). Panel M: Simulated pDOS of B p-states for rect-1Hₜₒₚ (blue), rect-1H_{bridge} (green), rect-2H (red), and v_{1/6}-30° borophene (purple). Panel N: LETS spectra taken on rect-v_{1/6}-30° borophane with hydrogen (red) and deuterium (orange) in addition to v_{1/6}-30° borophene (purple). The stretch modes of rect-1H_{bridge} and rect-2H structures are shown as insets. Simulated vibrational energies of rect-1H(D)_{bridge} and rect-2H(D) structures are labeled with black lines on the LETS spectra.

FIG. 3 shows Rect-v_{1/6}-30° borophane work function characterization according to embodiments of the invention. Panel A: FER spectra taken on Ag(111) (blue), v_{1/6}-30° borophene (purple), and rect-v_{1/6}-30° borophane (red). The tunneling current was held constant (100 pA) under feedback control while allowing the tip-sample distance to change during the FER measurement. The Δz-V_{bias} curves were simultaneously measured and are shown as navy lines in panel A. Panel B: Side view of the calculated local potential distribution above the surface of the rect-2H structure. The vertical green and blue lines represent the locations of the H atoms in the B—H_{bridge}—B and B—Hₜₒₚ bonds in the rect-2H structure, respectively. Corresponding line profiles of the potential distribution versus height are shown in the right panel, indicating that the difference in height is ˜3.0 Å between the points when the two line profiles reach above the vacuum level. Panel C: Magnified plots of FER spectra and corresponding Δz-V_{bias} curves of rectangular v_{1/6}-30° borophane, showing a change in tip distance of ˜3.1 Å between the split FER peaks. Panel D: ln|I|−z curves measured on Ag(111) (blue), rectangular v_{1/6}-30° borophane (red), and v_{1/6}-30° borophene (purple). The slopes of these plots are proportional to the apparent tunneling barrier height (Φₐₚ), as shown in the inset. Panel E: Comparison of the work functions of Ag(111), rectangular v_{1/6}-30° borophane, and v_{1/6}-30° borophene extracted from the apparent tunneling barrier height (blue), FER (green), and DFT (orange), respectively.

FIG. 4 shows stability of borophane in ambient conditions according to embodiments of the invention. Panels A-B: XPS spectrum and AFM image of mixed-phase v_{1/5}/v_{1/6}-30° borophene after ambient exposure for 1 hour. Panels C—H: XPS spectra and AFM images of mixed-phase v_{1/5}/v_{1/6}-30° borophane after ambient exposure for 1 hour (Panels C-D), 1 day (Panels E-F), and 1 week (Panels G-H).

FIG. 5 shows Derivative STM images of low coverage hydrogen adatoms (highlighted as yellow protrusions) on mixed-phase borophene (hydrogen dosing condition: 1.0×10⁻⁷ mbar for 5 min) according to embodiments of the invention. Panels A and C: Derivative STM images of low coverage hydrogen adatoms (highlighted as yellow protrusions) on mixed-phase borophene. Panels B and D: Enlarged STM images showing selective adsorption of hydrogen atoms on v_{1/6} compared to v_{1/5} borophene. Scanning conditions: (Panel A) V_{S}=30 mV, I_{T}=100 pA; (Panel B) V_{S}=20 mV, I_{T}=100 pA; (Panel C) V_{S}=60 mV, I_{T}=100 pA; (Panel D) V_{S}=20 mV, I_{T}=100 pA.

FIG. 6 shows STM images of high-coverage hexagonal v_{1/6} borophane according to embodiments of the invention. Panels A-B: STM images of high-coverage hexagonal v_{1/6} borophane with a bare STM tip (inset: FFT of image B, scale bar: 2 nm⁻¹). Panels C-D: STM images of hexagonal v_{1/6} borophane with a bare STM tip (Panel C) and CO-functionalized STM tip (Panel D). The green arrow indicates a v_{1/5} borophane line defect. Panels E-F: STM images of low-coverage hexagonal v_{1/6} borophane with a bare STM tip (E) and a CO-functionalized STM tip (F). Scanning conditions: (Panel A) V_{S}=80 mV, I_{T}=200 pA; (Panel B) V_{S}=10 mV, I_{T}=200 pA; (Panel C) V_{S}=50 mV, I_{T}=100 pA; (Panel D) V_{S}=10 mV, I_{T}=100 pA; (Panel E) V_{S}=10 mV, I_{T}=200 pA; (Panel F) V_{S}=30 mV, I_{T}=100 pA. Hydrogen dosing conditions: (panels A-B) 1.0×10⁻⁶ mbar for 10 min; (panels C-D) 1.0×10⁻⁶ mbar for 10 min.

FIG. 7 shows STM images of rectangular v_{1/6}-30 borophane with a bare STM tip (panel A) (V_{S}=10 mV, I_{T}=100 pA) and a CO-functionalized STM tip (panel B) (V_{S}=10 mV, I_{T}=500 pA) according to embodiments of the invention. The green arrows indicate the inserted v_{1/5}-30° borophane line defect. Hydrogen dosing condition: 2.5×10⁻⁶ mbar for 10 min.

FIG. 8 shows STM images of a v_{1/6}-30° borophane domain according to embodiments of the invention. Panels A and C: STM images of a v_{1/6}-30° borophane domain with a high coverage of the rectangular phase (V_{S}=20 mV, I_{T}=100 pA). Panels B and D: Corresponding derivative STM images showing higher contrast (V_{S}=10 mV, I_{T}=500 pA). Hydrogen dosing condition: 5.0×10⁻⁶ mbar for 2 min.

FIG. 9 shows energy landscape of hydrogen adsorption on v_{1/6}-30° borophene according to embodiments of the invention. Adsorption energies are calculated while only allowing H atoms to relax in the z-direction. Panel A: The H adsorption energy landscape on bare v_{1/6}-30 borophene, showing the lowest adsorption energy on the H_{bridge} site. Panel B: The energy landscape for the second H adsorption by keeping the initial H_{bridge} atom fixed on v_{1/6}-30° borophene, resulting in the lowering of the adsorption energy on the Hₜₒₚ site.

FIG. 10 shows top views and total energy landscapes of some borophane structures according to embodiments of the invention. Panels A-C: Top views of the rect-1Hₜₒₚ (panel A), rect-1H_{bridge} (panel B), and rect-2H (panel C) structures with the v_{1/6}-30° borophene/Ag(111) substrate frozen at the lowest energy alignment. Panels D-F: The total energy landscapes of translated borophane structures of t-rect-1Hₜₒₚ (panel D), t-rect-1H_{bridge} (panel E), and t-rect-2H (panel F). Panels G-I: Top views of the t-rect-1Hₜₒₚ (panel G), t-rect-1H_{bridge} (panel H), and t-rect-2H (panel I) structures at their lowest total energy alignments.

FIG. 11 shows simulated STM images of the translated borophane structures according to embodiments of the invention. Panel A: t-rect-1Hₜₒₚ. Panel B: t-rect-1H_{bridge}. Panel C: t-rect-2H.

FIG. 12 shows STM topography image of v_{1/6}-30° borophane with rectangular structures (Vₛ=1.2 V, Iₜ=100 pA) (panel A) and the corresponding differential tunneling conductance map (panel B), according to embodiments of the invention.

FIG. 13 shows STS spectra taken on different borophane polymorphs according to embodiments of the invention.

FIG. 14 shows simulated pDOS of B p-states from the translated configurations of t-rect-2H (red), t-rect-1Hₜₒₚ (blue), t-rect-1H_{bridge} (green), and v_{1/6}-30° borophene (purple), where the t-rect-2H structure shows a peak at ˜0.93 eV, according to embodiments of the invention.

FIG. 15 shows Electron densities mapped at the characteristic peak of (panel A) rect-2H and (panel B) t-rect-2H structures according to embodiments of the invention. The characteristic peak of the rect-2H structure (1.21-1.25 eV) is contributed from the Hₜₒₚ sites, while that of the t-rect-2H structure (0.91-0.95 eV) originates from both the Hₜₒₚ and H_{bridge} sites.

FIG. 16 shows comparison of change in electronic charge density of the DFT predicted vibrational modes of the rect-2H structure (mode 1: stretch mode of the B—H bonds at 311 meV; mode 2: stretch mode of B—H—B bonds at 240 meV) according to embodiments of the invention. Net electronic charge density isosurfaces are plotted at a value of 1E-5. Panels A-B: The change in electronic density of the rect-2H structure with atoms displaced +10% and −10% of the eigenvectors of mode 1, respectively. Panel C: The difference between panel A and panel B. Panels D-E: The change in electronic density of the rect-2H structure with atomic displacements +10% and −10% of the eigenvectors of mode 2, respectively. Panel F: The difference panel D and panel E. The charge distribution in positive and negative displacements are similar in mode 1 but different in mode 2, which explains the small cross-section of mode 2 in LETS measurements.

FIG. 17 shows (panel A) energy diagram of the STM tip-sample junction in the field emission tunneling regime, where E_{vac}: vacuum level, E_{F}: Fermi level, V_{bias}: sample bias, z₀: initial tip-sample distance, Δz: tip-sample displacement during FER measurements, Φ_{S}, Φ_{T}: sample, tip work functions, and (panel B) extracted and fitted FER peak energies versus n^{2/3} (n≥3) following eq. (1), according to embodiments of the invention.

FIG. 18 shows a side view of the local potential distribution above the surface of the rect-1Hₜₒₚ structure according to embodiments of the invention. The vertical green and blue lines represent H_{bridge} and Hₜₒₚ sites, respectively. Corresponding line profiles of the potential distribution versus height are shown in the right panel.

FIG. 19 shows (panel A) FER spectra taken on hexagonal v_{1/6}-30 borophane (green) and Ag(111) (blue) (setpoint: constant current at 100 pA), and (panel B) fitted plots of FER peak energies versus n^{2/3} (n≥3) following eq. (1), according to embodiments of the invention.

FIG. 20 shows the estimated net charge on boron (green) and hydrogen (yellow) atoms based on Bader charge analysis for (panel A) v_{1/6}−30° borophene, (panel B) rect-1H_{bridge}, (panel C) rect-1Hₜₒₚ, and (panel D) rect-2H structures, according to embodiments of the invention.

FIG. 21 shows (panel A) STM topography image of a v_{1/6}-30° borophane island and (panel B) the simultaneously acquired |d ln I/dz| image (V_{S}=110 mV, I_{T}=100 pA), (panel C) zoomed-in STM topography image of rectangular and hexagonal v_{1/6}-30° borophane phases and (panel D) the simultaneously acquired |d ln I/dz| image (V_{S}=5 mV, I_{T}=500 pA), where rect-v_{1/6}-30° borophane shows lower apparent tunneling barrier height compared to hex-v_{1/6}-30° borophane.

FIG. 22 shows thermal stability of borophane according to embodiments of the invention. Panels A-B: STM images of the initial borophane surface. Panels C-D: STM images of the borophane sample after annealing at ˜200° C. for 1 hour. Panels E-F: STM images of the borophane sample after annealing at ˜300° C. for 1 hour, resulting in pristine borophene with no apparent degradation. Scanning conditions: (panel A) V_{S}=30 mV, I_{T}=100 pA; (panel B) V_{S}=5 mV, I_{T}=100 pA; (panel C) V_{S}=400 mV, I_{T}=100 pA; (panel D) V_{S}=30 mV, I_{T}=100 pA; (panel E) V_{S}=500 mV, I_{T}=100 Pa; (panel F) V_{S}=10 mV, I_{T}=300 pA.

FIG. 23 shows STM and corresponding derivative images according to embodiments of the invention. Panels A-B: STM and corresponding derivative images of mixed-phase v_{1/5} and v_{1/6}-30° borophene with small domain sizes of 20-40 nm (V_{S}=100 mV, I_{T}=100 pA). The v_{1/6}-30° borophene domains are marked with pink color. Panels C-D: STM and corresponding derivative images of a large v_{1/6}-30° borophene with domain size over 100 nm (V_{S}=50 mV, I_{T}=100 pA).

FIG. 24 shows a wide-range XPS spectrum of mixed-phase v_{1/5} and v_{1/6}-30° borophane (hydrogen dosing condition: 2.5×10⁻⁶ mbar for 10 min) after ambient exposure for 1 hour.

### DETAILED DESCRIPTION OF THE INVENTION

The invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this specification will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term are the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures. is turned over, elements described as being on the “lower” side of other elements would then be oriented on “upper” sides of the other elements. The exemplary term “lower”, can, therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this specification, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

As used in this specification, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in this specification, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in a different order (or concurrently) without altering the principles of the invention.

Borophene refers to the family of synthetic two-dimensional (2D) polymorphs of boron, which has attracted significant attention due to anisotropic metallicity, correlated electron phenomena, and diverse superlattice structures. However, borophene rapidly oxidizes when exposed to air, which has confined experimental characterization to ultrahigh vacuum (UHV) conditions, thus motivating chemical passivation approaches. Towards this end, this invention achieves covalent hydrogenation of borophene (i.e., ‘borophane’) through exposure to atomic hydrogen in UHV, resulting in a diverse set of borophane polymorphs. Borophane polymorphs are metallic with modified local work functions compared to pristine borophene, with the most prevalent borophane polymorph found to include two-center-two-electron (2c2e) boron-hydrogen (B—H) bonds and three-center-two-electron (3c2e) boron-hydrogen-boron (B—H—B) bonds. Hydrogenation acts as a robust passivation scheme for borophene with multiple borophane polymorphs suppressing measurable oxidation for several days following ambient exposure. Since this hydrogenation can be reversibly removed through thermal annealing, borophane can be returned to pristine borophene following ambient processing, thus presenting significant flexibility in borophene sample preparation. Overall, this invention reveals the richness of borophane chemistry, which is likely to inspire and motivate further exploration of covalently modified borophene polymorphs.

In one aspect, the invention relates to a method of synthesizing borophane polymorphs. The method in one embodiment comprises growing borophene on a substrate in an ultrahigh vacuum (UHV) chamber; and performing hydrogenation of the borophene in situ to obtain a diverse set of borophane polymorphs. Hydrogenation of borophene results in the synthesis of ‘borophane’ polymorphs, which possess modified local work functions and improved chemical passivation characteristics in ambient conditions.

In some embodiments, the UHV chamber has a base pressure of about 1.0×10⁻¹⁰ mbar during the borophene growth.

In some embodiments, the substrate comprises a substrate having a metal film formed of Ag, Au, Cu, Al, or Ir.

In some embodiments, the substrate comprises an atomically clean Ag(111) substrate having about 480-720 nm thick Ag(111) on a mica substrate.

In some embodiments, the substrate is obtained by cleaning the mica substrate via repeated cycles of Ar⁺ sputtering followed by annealing at about 450-550° C.

In some embodiments, said growing the borophene on the substrate comprises depositing boron on the substrate at a substrate temperature.

In some embodiments, said depositing the boron is performed by electron-beam evaporation of a solid boron rod, or high temperature effusion of the solid boron rod in a high temperature effusion cell.

In some embodiments, the solid boron rod has a purity of about 99.999-99.99999% boron.

In some embodiments, the borophene grown on the substrate has a dominant borophene polymorph determined by a substrate temperature.

In some embodiments, the substrate temperature is at about 320-660° C. during boron deposition.

In some embodiments, said hydrogenation is performed in situ by exposing the borophene to atomic hydrogen.

In some embodiments, the atomic hydrogen is generated by dissociation of the molecular hydrogen with a tungsten filament, or a platinum filament, or an iridium filament, or platinum/iridium filament, or by a hydrogen atom beam source that thermally crack molecular hydrogen into atomic hydrogen.

In some embodiments, during hydrogenation, the borophene is maintained at room temperature and directly faced the tungsten filament with a distance of about 8-12 cm.

In some embodiments, the chamber pressure during hydrogenation is maintained at about 1.0×10⁻⁷-5.0×10⁻⁶ mbar for about 1-20 min.

In another aspect, the invention relates to borophane polymorphs being synthesized according to the above disclosed method.

In some embodiments, the borophane polymorphs are metallic with modified local work functions compared to pristine borophene.

In some embodiments, the borophane polymorphs can be reversibly returned to pristine borophene via thermal desorption of hydrogen.

In some embodiments, the borophane polymorphs comprises at least eight borophane polymorphs.

In some embodiments, the borophane polymorphs comprises v_{1/5} borophane with square H and honeycomb H patterns, v_{1/5}-30° borophane with staggered rectangular H and zigzag H patterns, v_{1/6} borophane with hexagonal H and disordered rectangular H patterns, and v_{1/6}-30° borophane with hexagonal H and rectangular H patterns, wherein H represents hydrogen atoms.

In some embodiments, the v_{1/6}-30° borophane with the rectangular H pattern (rect-v_{1/6}-30° borophane) includes two-center-two-electron (2c2e) boron-hydrogen (B—H) bonds and three-center-two-electron (3c2e) boron-hydrogen-boron (B—H—B) bonds.

In some embodiments, the rect-v_{1/6}-30° borophane has a lower work function than v_{1/6}-30° borophene.

In some embodiments, the borophane polymorphs have tunable stoichiometric ratios of boron and hydrogen.

In some embodiments, the borophane polymorphs have negligible oxidation for multiple days following ambient exposure.

In some embodiments, the borophane polymorphs are metallic with modified local work functions compared to pristine borophene.

In some embodiments, the borophane polymorphs can be reversibly returned to pristine borophene via thermal desorption of hydrogen.

Borophene has been intensely explored due to its unique properties including 2D anisotropic metallicity, high mechanical strength and flexibility, and phonon-mediated superconductivity. However, borophene rapidly oxidizes when exposed to air, which poses significant challenges for its practical implementation. The hydrogen passivation scheme demonstrated in this invention offers an opportunity to integrate borophene into practical devices that are relevant to the fields of electronics, optoelectronics, sensing, energy-harvesting, quantum information, and related technologies. The invention may have widespread applications in the fields including, but are not limited to, optoelectronics, high frequency logic, sensing, medical imaging, energy conversion and storage, and quantum information technologies.

This invention discloses the covalent chemical functionalization and passivation of borophene for the first time. Among other things, the invention provides a number of advantages.
Borophane is a hydrogenated analogue of borophene, which is a new synthetic 2D material with diverse bonding geometry and anisotropic features.
Existing synthetic methods for hydrogen boride nanosheets are based on chemical reactions involving inorganic salts. However, atomically well-defined synthesis and characterization of borophane polymorphs have not yet been achieved.
The invention offers a straightforward and effective hydrogenation scheme through precisely controlled dosing of atomic hydrogen in UHV, which results in ordered borophane polymorphs with tunable stoichiometric ratio of boron and hydrogen.
Unlike pristine borophene that oxidizes almost instantaneously in ambient conditions, the borophane shows negligible oxidation according to X-ray photoelectron spectroscopy (XPS) even after 1 week of ambient exposure.

The hydrogenation of borophene can be viewed as a reversible passivation scheme in which the hydrogenation can be removed to regain pristine borophene once ambient processing is complete and/or robust encapsulation layers are applied.

These and other aspects of the invention are further described below. Without intent to limit the scope of the invention, exemplary instruments, apparatus, methods, and their related results according to the embodiments of the invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### EXAMPLE

### Synthesis of Borophane Polymorphs Via Hydrogenation of Borophene

Borophene refers to the family of synthetic two-dimensional polymorphs of boron, which has attracted significant attention due to anisotropic metallicity, correlated electron phenomena, and diverse superlattice structures. While borophene heterostructures have recently been realized, ordered chemical modification of borophene has not yet been reported. In this exemplary study, borophane polymorphs were synthesized by hydrogenating borophene with atomic hydrogen in ultrahigh vacuum. Through atomic-scale imaging, spectroscopy, and first principles calculations, the most prevalent borophane polymorph is shown to possess a combination of two-center-two-electron (2c2e) boron-hydrogen (B—H) and three-center-two-electron (3c2e) boron-hydrogen-boron (B—H—B) bonds. Borophane polymorphs are metallic with modified local work functions that can be reversibly returned to pristine borophene via thermal desorption of hydrogen. Hydrogenation also provides chemical passivation as borophane is shown to suppress measurable oxidation for multiple days following ambient exposure.

In this exemplary example, hydrogenation of borophene is achieved by exposing borophene to atomic hydrogen in ultrahigh vacuum. Similar to the high degree of polymorphism in borophene, eight different borophane polymorphs are observed. Since it can achieve high surface coverage and possesses a highly ordered structure, rectangular v_{1/6}-30° borophane (abbreviated as rect-v_{1/6}-30°) is explored thoroughly to reveal its bonding structure and properties. In particular, by combining scanning tunneling microscopy/spectroscopy (STM/STS), inelastic electron tunneling spectroscopy (JETS), and density functional theory (DFT), the bonding in rect-v_{1/6}-30° borophane is found to include two-center-two-electron (2c2e) B—H bonds and three-center-two-electron (3c2e) B—H—B bonds. In situ local work function measurements support theoretical predictions that rect-v_{1/6}-30° borophane has a lower work function than v_{1/6}-30° borophene. In addition, unlike pristine borophene that oxidizes almost instantaneously in ambient conditions, borophane shows negligible oxidation according to X-ray photoelectron spectroscopy (XPS) even after 1 week of ambient exposure.

### Borophane Polymorphs

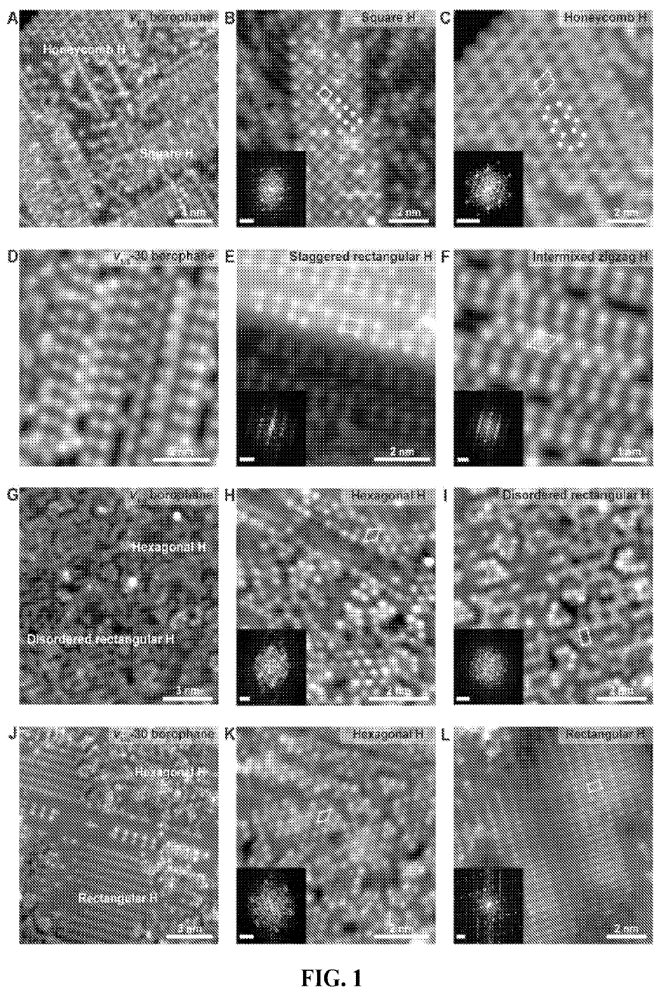

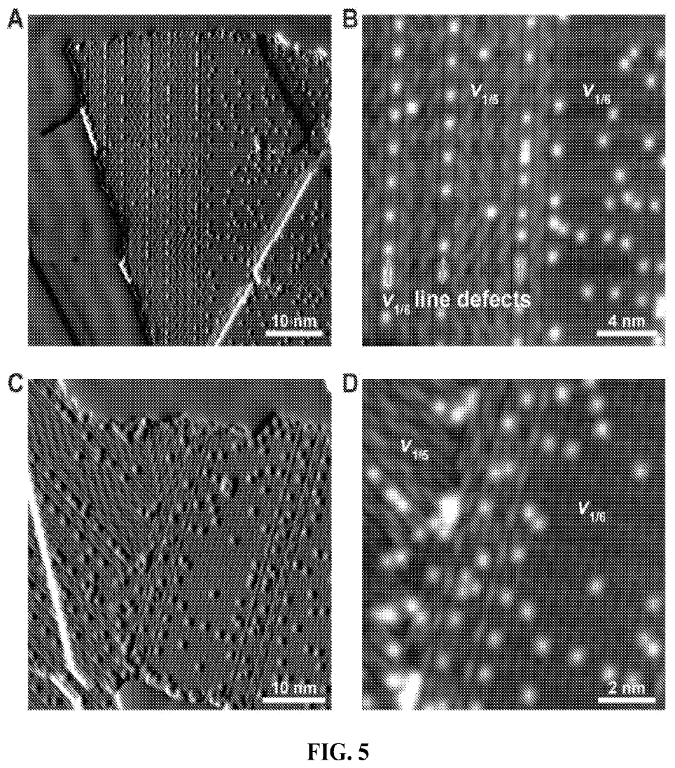

Borophene was grown on atomically clean Ag(111) substrates in UHV by elemental boron evaporation with the dominant borophene polymorph determined by the substrate temperature. Subsequent hydrogenation was performed in situ by exposing the borophene sample to atomic hydrogen that was generated by cracking molecular hydrogen with a hot tungsten filament. Following this procedure, STM revealed bright protrusions on the borophene surface, which were attributed to hydrogen adatoms, as shown in FIG. 5. While this observation is qualitatively similar to hydrogen adsorption on graphene, chemical modification of borophene is likely to be more complex than graphene because of its multi-centered bonding configurations and anisotropic features. At least eight borophane polymorphs are derived from the four most common borophene phases (i.e., v_{1/5}, v_{1/5}-30°, v_{1/6}, and v_{1/6}−30°. For v_{1/5} borophane, STM images reveal two distinctive structures with square H and honeycomb H patterns, as shown in panel A of FIG. 1. Panel B of FIG. 1 shows the well-ordered square v_{1/5} borophane structure and corresponding inset fast Fourier transform (FFT) pattern. The extracted lattice constant (0.43±0.02 nm) agrees well with the inter-row distance of v_{1/5} borophene, indicating a commensurate adsorption structure. The honeycomb v_{1/5} borophane structure shown in panel C of FIG. 1 possesses a unit cell of 0.60±0.03 nm by 0.80±0.03 nm and an angle of 103° (±1°), which is composed of elongated hexagons that can be broken up into zigzag rows. The edge lengths of the zigzag match that of the square v_{1/5} borophane structure (0.43±0.02 nm). Unlike v_{1/5} borophene, v_{1/5}-30° borophene has stripe-like undulations along its staggered hollow hexagons (fills). As a result, staggered rectangular H structures intermixed with zigzag H rows are formed along the undulations of v_{1/5}-30° borophene, as depicted in panel D of FIG. 1. The staggered rectangular H structure possesses a rectangular unit cell of 0.38±0.03 nm by 0.60 nm±0.03 nm, as shown in panel E of FIG. 1. Intermixed zigzag H rows are also observed in between the staggered rectangular H structures, with a rhombus unit cell with side length of 0.60±0.02 nm, as shown in panel F of FIG. 1.

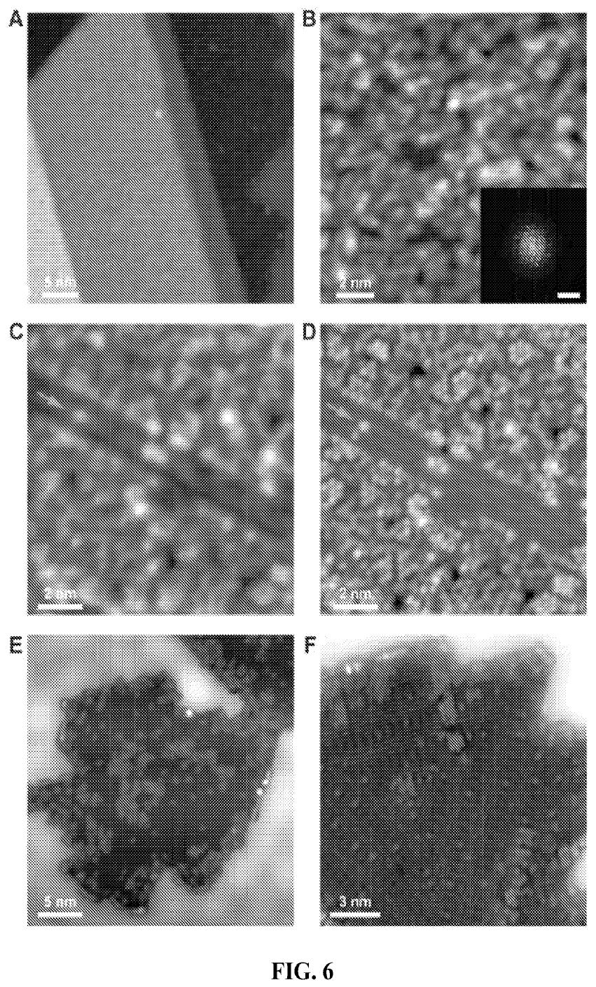

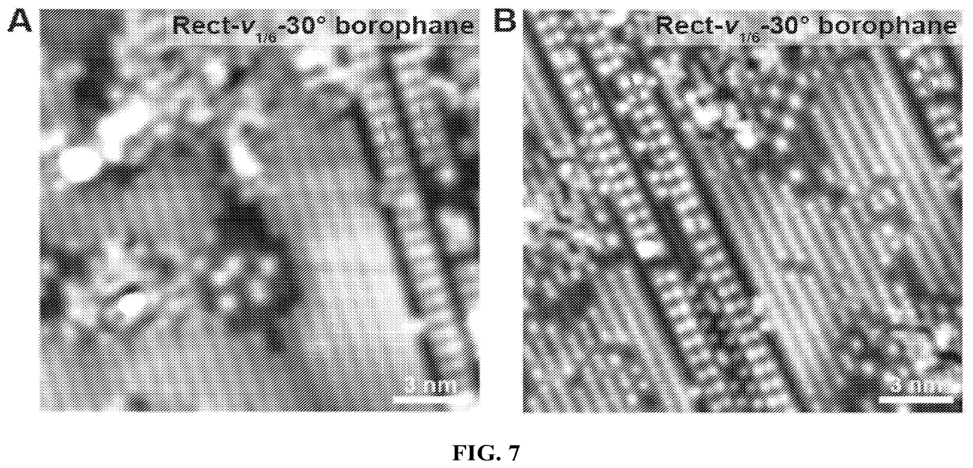

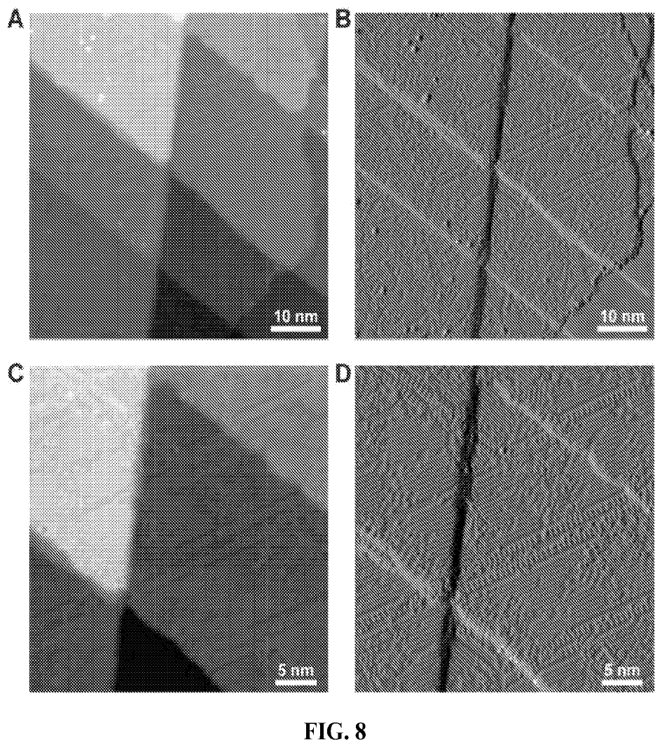

Additional borophane structures are observed following the hydrogenation of v_{1/6} borophene. In this case, v_{1/6} borophane is characterized with both hexagonal and rectangular H patterns. The hexagonal H pattern is most prevalent for v_{1/6} borophane with a unit cell of 0.34±0.02 nm by 0.35±0.02 nm, as shown in panel H of FIG. 1. Another coexisting v_{1/6} borophane polymorph shows a disordered rectangular H structure, as shown in panel I of FIG. 1, which is composed of a rectangular lattice with vacancies and dislocations. Additional complex patterns on v_{1/6} borophane were imaged as disordered structures with a bare metal tip, as shown in FIG. 6. In contrast, v_{1/6}-30° borophane distinguishes itself with a highly ordered rectangular H structure, as shown in panel J of FIG. 1. Compared to the bare tip STM image with an apparent striped structure, rect-v_{1/6}-30° borophane is resolved as an ordered rectangular lattice using CO-functionalized tip STM imaging (CO-STM) (FIG. 7). The unit cell of rect-v_{1/6}-30° borophane is 0.50±0.02 nm by 0.30±0.02 nm, as shown in panel L of FIG. 1, which matches v_{1/6}-30° borophene. Although some hexagonal H patterns are observed on v_{1/6}-30° borophane, as shown in panel K of FIG. 1, rect-v_{1/6}-30° borophane is the dominant phase, as shown in FIG. 8. As a result of its predominance and highly ordered structure, rect-v_{1/6}-30° borophane was selected for in-depth further investigation.

### Structural Characterization of Rect-v_{1/6}-30° Borophane

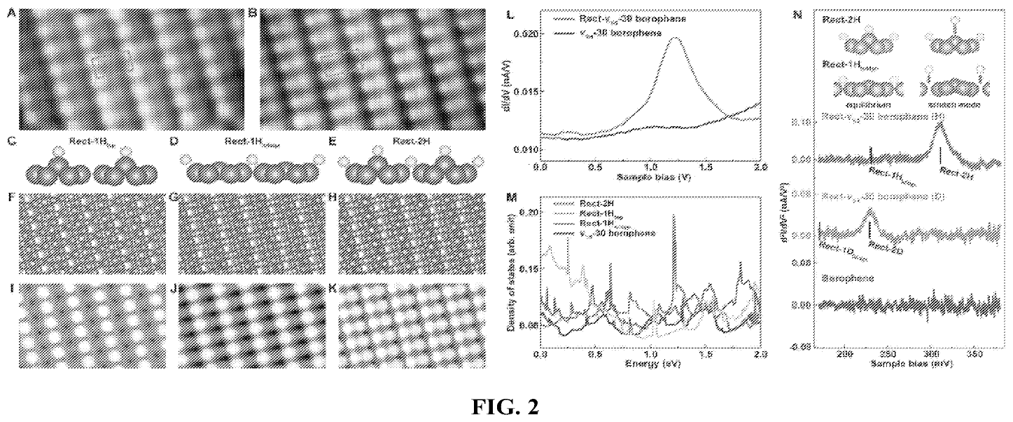

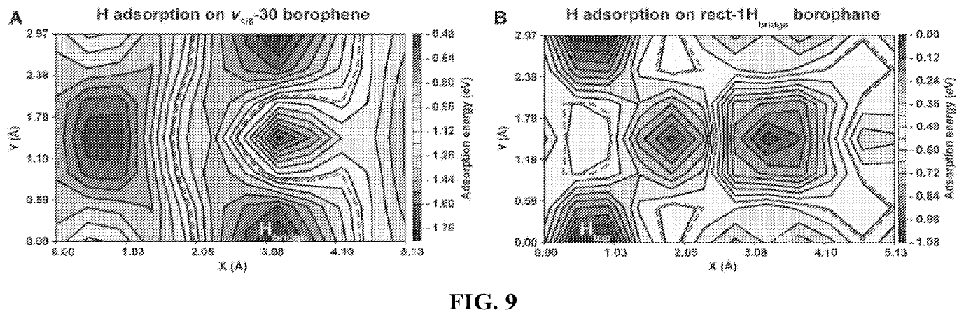

High-resolution CO-STM images of rect-v_{1/6}-30° borophane acquired at different scanning conditions are shown in panels A-B of FIG. 2. Within the rectangular unit cell (indicated by the green box), a bright protrusion appears in conjunction with a neighboring dimmer protrusion. These ladder-like patterns are more prominent when acquired at lower biases (i.e., closer tip-sample spacing), as shown in panel B of FIG. 2. DFT calculations identified three stable hydrogen adsorption structures on v_{1/6}-30° borophene that possessed rectangular unit cells with lattice constants of 0.50 nm by 0.30 nm (see FIG. 9 and Table 1 for detailed adsorption energy landscapes). The rect-1H_{top/bridge} structure possesses one H atom adsorbed on the bridge/top site of v_{1/6}-30° borophene, forming a B—H bond/B—H—B ‘banana’ bond as shown in panels C, F and panels D, G of FIG. 2, respectively. On the other hand, the rect-2H structure is composed of two adsorbed H atoms (Hₜₒₚ and H_{bridge}) in the rectangular unit cell, as depicted in panels E, H of FIG. 2. The calculated B—H bond lengths in the proposed borophane structures are 133 pm (H_{bridge} site) and 121 pm (Hₜₒₚ site), respectively. The values of these bond lengths are comparable with the 3c2e B—H—B bond length of 131 pm in diborane and the 2c2e B—H bond length of 119 pm in borane, indicating the formation of covalent bonds in the borophane structures.

TABLE 1
DFT calculated total energies (eV), adsorption energies (eV/atom)
with PBE functional and opt-b88-vdw functional, and work functions (eV)
of ν_{1/6} −30° borophene, rect-1H_{bridge}, rect-1Hₜₒₚ, and rect-2H
structures in addition to translated structures: t-rect-1H_{bridge},
t-rect-1Hₜₒₚ, and t-rect-2H.

| | Total energy | | Adsorption energy | | Work |
|---|---|---|---|---|---|
| | (eV) | | (eV/atom) | | function |
| | PBE | opt-b88 vdw | PBE | opt-b88 vdw | Φ (eV) |
| ν_{1/6} −30° | −68.644 | −21.491 | — | — | 4.62 |
| borophene | | | | | |
| Rect-1H_{bridge} | −71.646 | −24.458 | −1.89 | −2.07 | 3.68 |
| Rect-1Hₜₒₚ | −72.105 | −25.032 | −2.34 | −2.64 | 5.27 |
| Rect-2H | −75.737 | −28.641 | −2.43 | −2.67 | 4.42 |
| t-Rect-1H_{bridge} | −71.873 | −24.676 | −2.13 | −2.30 | 3.58 |
| t-Rect-1Hₜₒₚ | −72.127 | −25.051 | −2.38 | −2.67 | 5.29 |
| t-Rect-2H | −76.101 | −29.005 | −2.62 | −2.86 | 4.51 |

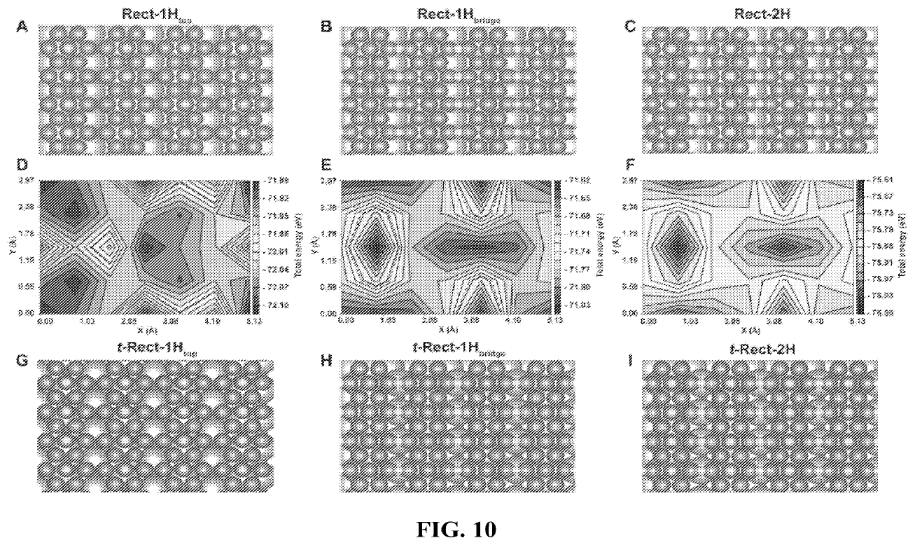

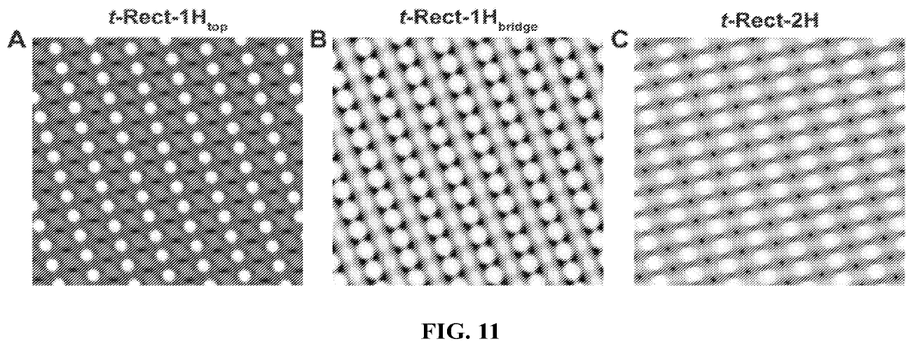

The simulated STM images from rect-1Hₜₒₚ (panel I of FIG. 2) and rect-1H_{bridge} (panel J of FIG. 2) reveal the contribution of electron densities from Hₜₒₚ/H_{bridge} atoms, while the ladder-like patterns are not apparent in these structures. On the other hand, the rect-2H structure (panel K of FIG. 2) most closely matches the experimentally observed ladder-like patterns. Although the H atoms (on the top and bridge sites) in the rect-2H structure are equidistant in a row, the electron density at the H_{bridge} site slightly shifts toward the Hₜₒₚ side in the simulated STM image, resulting in the ladder-like pattern. It is worth noting that the uneven brightness in the ladder-like patterns (panels A-B of FIG. 2) is likely due to the height difference of ˜0.92 Å in the Hₜₒₚ and H_{bridge} sites. Periodic (infinite) and defect-free DFT calculations predict a different lowest-energy alignment between borophane and Ag (‘shifted’ alignment) compared to borophene and Ag (‘original’ alignment) (FIG. 10). This calculation implies that a perfect (i.e., infinite and defect-free) borophene sheet will shift on the Ag substrate upon hydrogen adsorption. However, the simulated STM images from this shifted borophane (FIG. 11) do not agree with experimental observations. The presence of borophene edges and defects likely prevents the shifting of borophene with respect to the Ag substrate upon H adsorption.

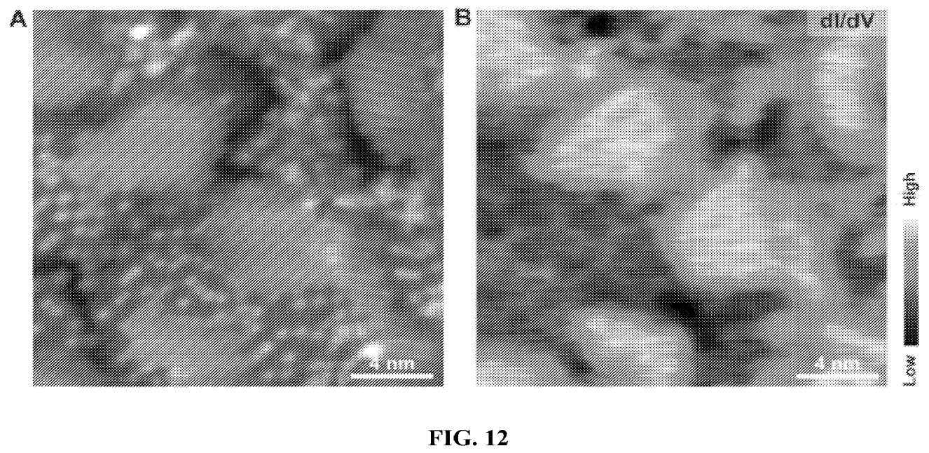

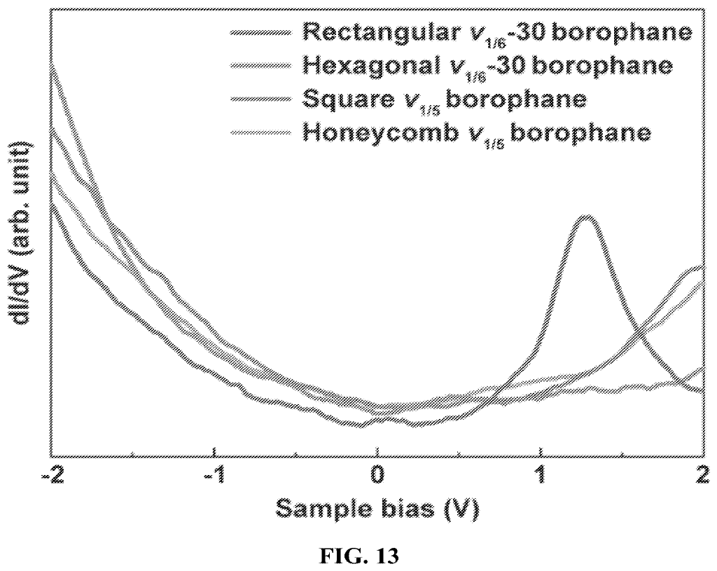

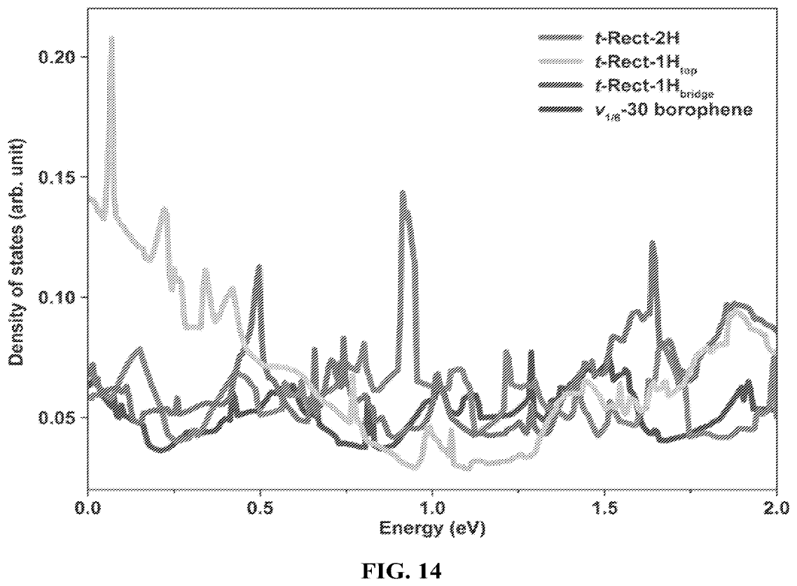

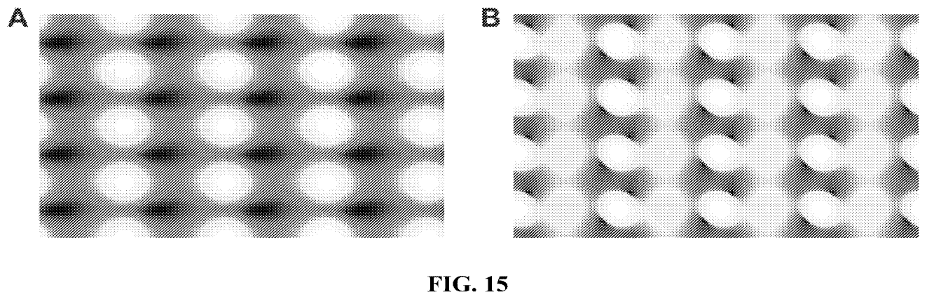

STS was also performed on rect-v_{1/6}-30° borophane to provide additional experimental evidence in support of the rect-2H structure. In particular, the differential tunneling conductance spectrum taken on rect-v_{1/6}-30° borophane shows a distinct peak at ˜1.2 V (panel L of FIG. 2 and FIG. 12), which is absent for v_{1/6}-30° borophene and other borophane polymorphs (FIG. 13). This experimental STS peak agrees well with the calculated projected density of states (pDOS) of boron p-states (averaged per atom) for the rect-2H structure, which also shows a sharp peak at ˜1.2 V that is not observed for the rect-1Hₜₒₚ and rect-1H_{bridge} structures (panel M of FIG. 2) or the shifted borophane alignments (FIG. 14). The electron density from this electronic state is mainly contributed from the Hₜₒₚ sites in the rect-2H structure, as plotted in the partial charge density map in FIG. 15. Moreover, STS revealed the metallic characteristic of borophane polymorphs (FIG. 13), which resembles that of borophene as 2D metals.

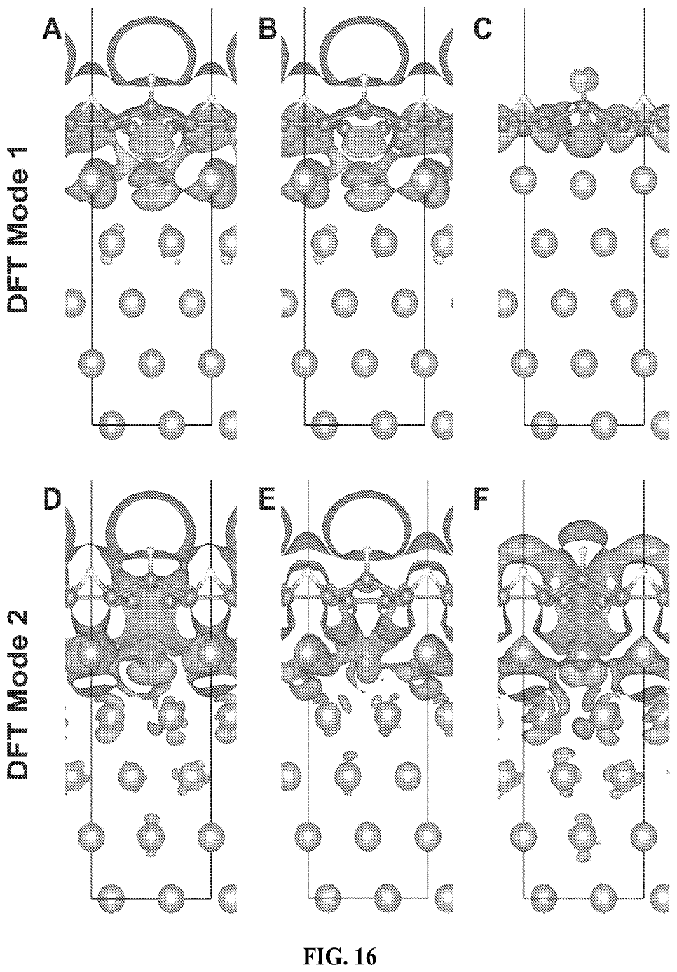

The bonding geometry of rect-v_{1/6}-30° borophane was further investigated by LETS measurements. Due to the sensitivity of vibrational spectra to isotopic identity, hydrogenated and deuterated rect-v_{1/6}-30° borophane samples were prepared for LETS characterization. The LETS spectra of rect-v_{1/6}-30° borophane with hydrogen (red) and deuterium (orange) in addition to pristine v_{1/6}-30° borophene (purple) are shown in panel N of FIG. 2. The inset shows the eigenvectors of the vibrational modes of hydrogen at both H_{bridge} and Hₜₒₚ sites. The peak at ˜310 (230) meV in the LETS spectra for rect-v_{1/6}-30° borophane with H (D) closely matches the theoretically calculated stretch mode of the B—H(D) bonds (top site) in the rect-2H(D) structures at 311 (229) meV. The same stretch mode (i.e., B—H(D) bond) is expected in the rect-1H(D) to p structures, with these vibrations calculated to be 308 (227) meV. In comparison, the B—H(D)-B bonds (bridge site) vibrations are not observed experimentally, which are calculated to be 240 (177) meV (rect-2H) or 231 (172) meV (rect-1H_{bridge}). The experimental absence of the stretch mode of the B—H(D)-B bonds can be explained by its small LETS cross-section (FIG. 16). Unlike the stretch mode of B—H(D) bonds, the stretch mode of B—H(D)-B bonds induces a net out-of-plane dipole with respect to displacement, resulting in negligible changes in tunneling rates with respect to displacement amplitude. Overall, the combination of STM, STS, and LETS provides strong evidence that rect-v_{1/6}-30° borophane possesses the rect-2H structure.

### Local Work Function Measurements

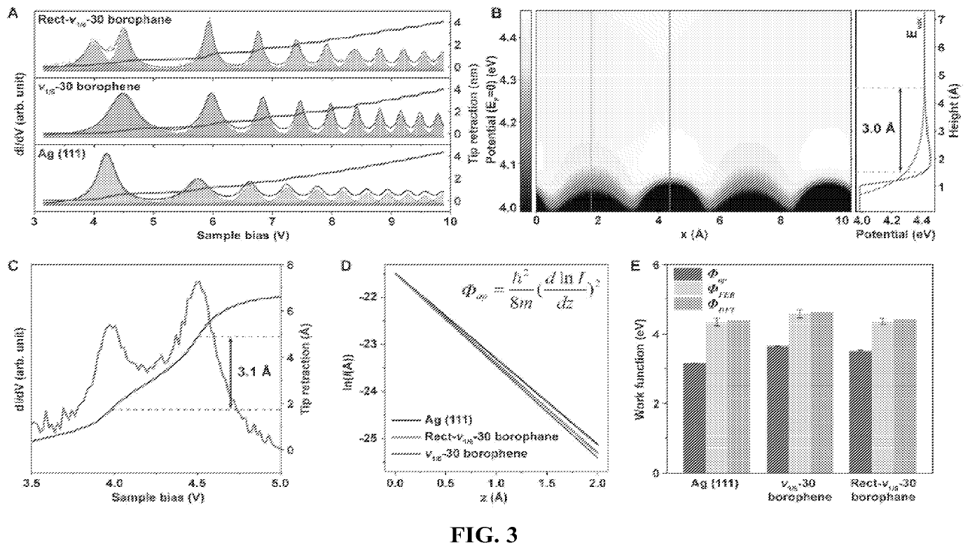

The local work function (LWF) of rect-v_{1/6}-30° borophane was probed with STM by measuring field-emission resonances (FERs), also known as Gundlach oscillations, which arise in the Fowler-Nordheim regime through standing-wave states in the tip-sample gap. Panel A of FIG. 3 shows FER spectra taken on Ag (blue), v_{1/6}-30° borophene (purple), and rect-v_{1/6}-30° borophane (red), respectively. The FER measurements were performed at a constant tunneling current of 100 pA with the resulting tip retraction (i.e., Δz-V_{bias}) curves being simultaneously recorded and plotted in panel A of FIG. 3. The first FER peak appears at ˜4.2 eV on Ag(111), consistent with previously reported results. In contrast, v_{1/6}-30° borophene shows its first FER peak at ˜4.5 eV, indicating an increased work function compared to pristine Ag(111). For rect-v_{1/6}-30° borophane, the first FER peak is split into two sub-peaks located at ˜4.0 eV and ˜4.5 eV. The energy splitting of the image states was previously reported on InAs(111) and attributed to surface potential corrugation.

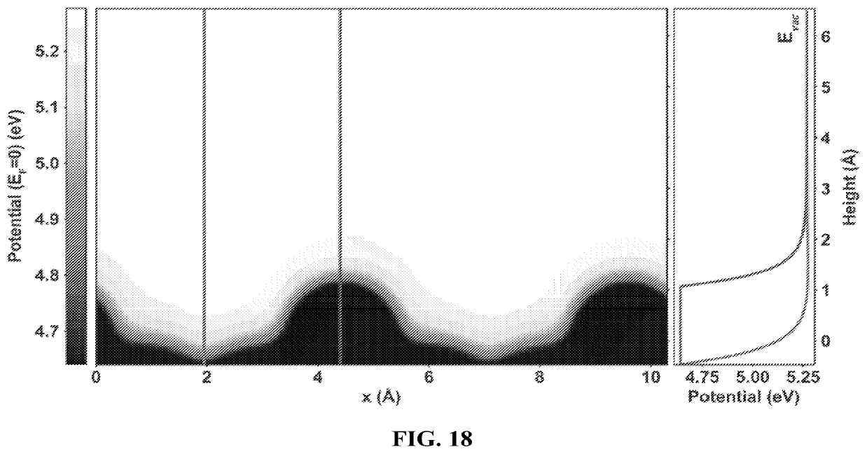

To better understand the surface potential for rect-v_{1/6}-30° borophane, DFT calculations with dipole correction were performed to simulate electrostatic potential profiles. Panel B of FIG. 3 shows the side view of the local potential distribution along the plane of adsorbed H atoms above the surface of the rect-2H structure. The green and blue vertical lines indicate the lateral position of the H atoms at the H_{bridge} and Hₜₒₚ sites, respectively. The potential profiles versus height along the green and blue lines are shown in the right panel of panel B of FIG. 3. Due to the large in-plane inhomogeneities across the rect-v_{1/6}-30° borophane unit cell, the potential rises sharply above Hₜₒₚ (blue line) and exceeds the far-field potential, whereas the potential increases gradually towards (but never exceeds) the far-field level above H_{bridge} (green line). The vertical extent of the region where the potential is above the vacuum level is 3.0 Å, which is consistent with the tip retraction height of 3.1 Å between the split initial peaks in the rect-v_{1/6}-30° borophane FER spectrum. The potential profile of the rect-1Hₜₒₚ structure is shown in FIG. 18 for comparison, where the potential above the Hₜₒₚ site decreases gradually instead of the sharp rise above the Hₜₒₚ site in the rect-2H structure. This result suggests that the energy splitting of the first FER peak for rect-v_{1/6}-30° borophane originates from the potential corrugation of the different local environments above the H_{bridge} and Hₜₒₚ sites.

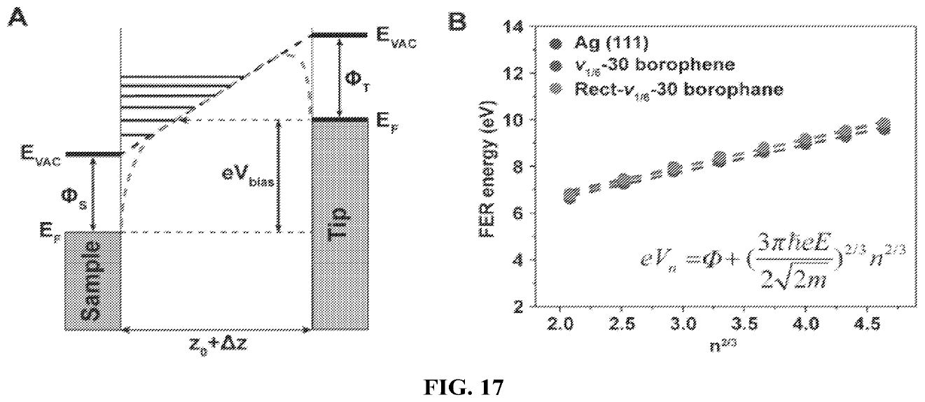

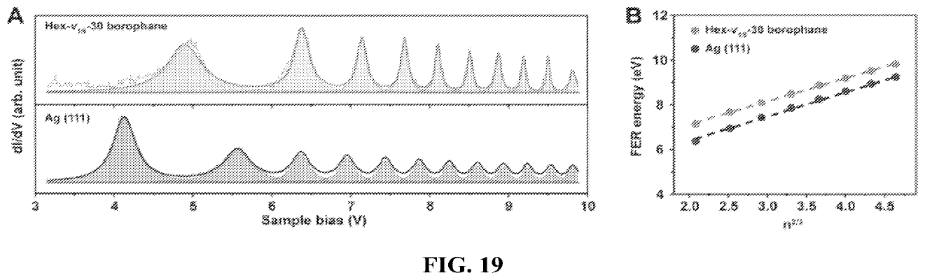

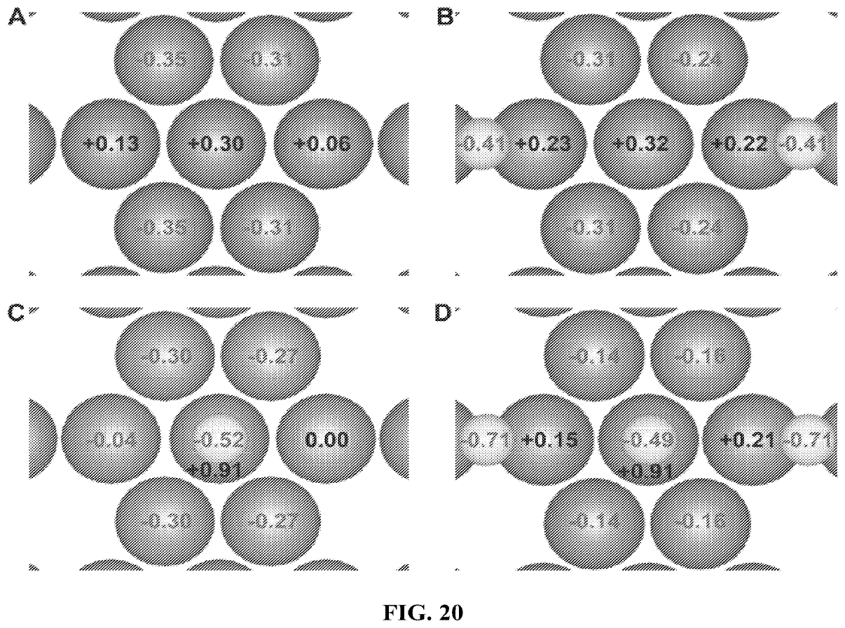

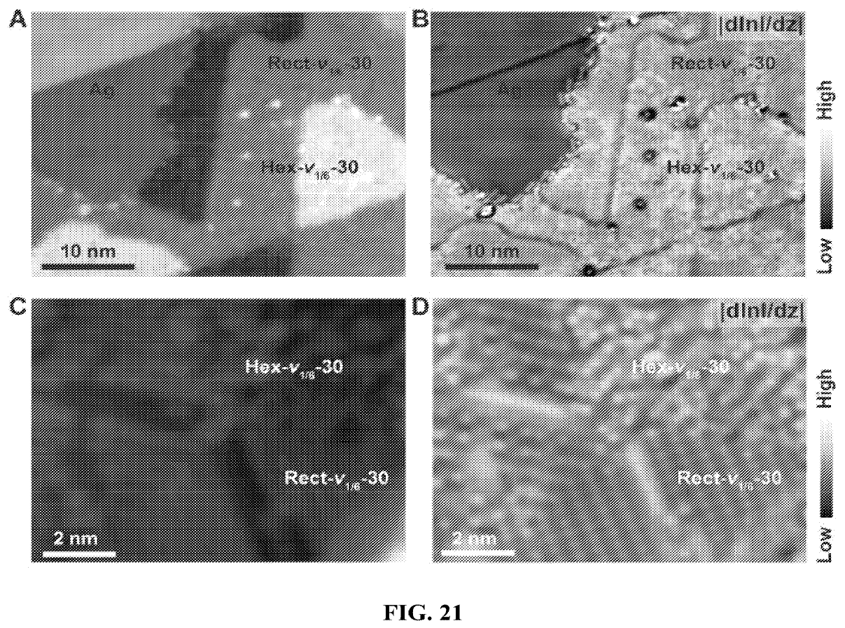

The LWFs for Ag(111), v_{1/6}-30° borophene, and rect-v_{1/6}-30° borophane were extracted from the FER spectra as 4.34±0.11 eV, 4.58±0.12 eV, and 4.36±0.09 eV, respectively (FIG. 17). These values agree well with DFT calculations that yielded LWFs of 4.39 eV, 4.62 eV, and 4.42 eV, respectively. Rect-v_{1/6}-30° borophane exhibits a slightly lower work function than v_{1/6}-30° borophene, indicating a change in areal dipole due to hydrogen adsorption. In contrast, hex-v_{1/6}-30° borophane shows a higher work function than v_{1/6}-30° borophene, which was extracted from the FER measurement in FIG. 19. The work function differences between these borophane polymorphs are a consequence of the different B—H bonding types and resulting areal dipoles as confirmed by Bader charge analysis (FIG. 20). The LWF differences are also supported by apparent barrier height measurements using I(z) spectroscopy. The lnI(z) plots of Ag(111), v_{1/6}-30° borophene, and rect-v_{1/6}-30° borophane are shown in panel D of FIG. 3, resulting in extracted apparent barrier heights of 3.15±0.004 eV, 3.65±0.004 eV, and 3.48±0.03 eV, respectively (see supplementary text for details). Despite the quantitative discrepancy between these extracted apparent barrier heights and the FER/DFT results due to the oversimplified approximation of the tunnel gap as a trapezoidal barrier, the apparent barrier height results still yield the correct qualitative trend in LWF, thus allowing apparent barrier height imaging to be used for spatial mapping of the LWF. For example, the spatial variations in LWF between borophane polymorphs and Ag(111) are visualized using |dlnI/dz| imaging in FIG. 21.

### Ambient Stability of Borophane

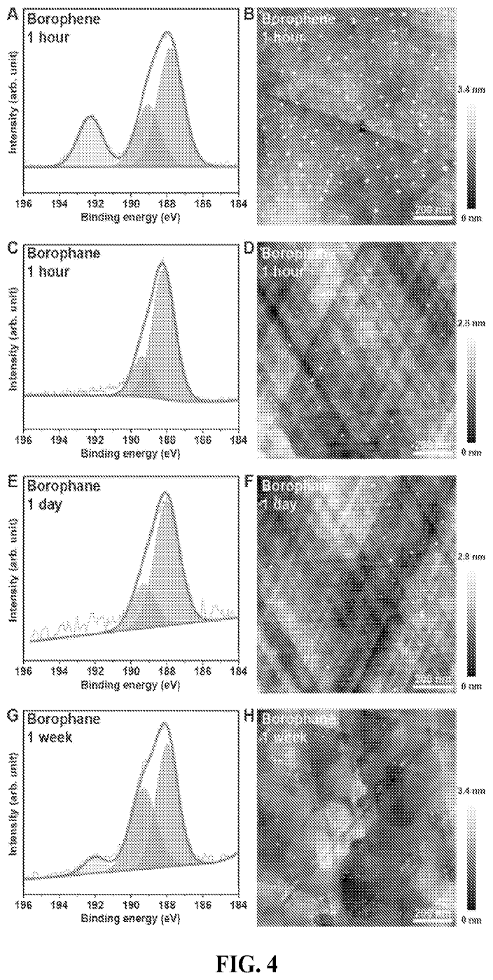

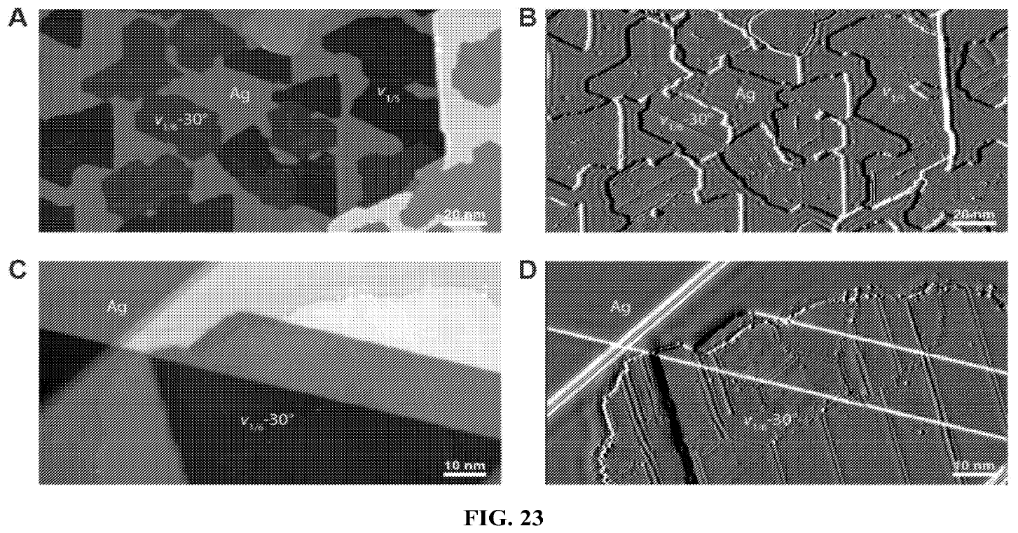

The ambient stability of borophane was evaluated using XPS and atomic force microscopy (AFM) measurements following different periods of ambient exposure. Unencapsulated borophene sheets chemically degrade in ambient conditions. We confirmed this result by performing XPS on unencapsulated mixed-phase v_{1/5}/v_{1/6}-30° borophene following 1 hour of ambient exposure at 20° C., relative humidity between 20%-50% (panel A of FIG. 4, see FIG. 23 for details). The resulting XPS spectrum was fit with three peaks centered at 187.8 eV, 189.1 eV, and 192.3 eV, with the two low binding energy peaks (green and blue) corresponding to the B—B bonds in borophene and the higher binding energy peak (yellow) corresponding to B—O bonds formed during ambient oxidation. Furthermore, the ex situ AFM image (panel B of FIG. 4) shows a rough surface decorated with particles that is consistent with the decomposition of borophene into boron oxides.

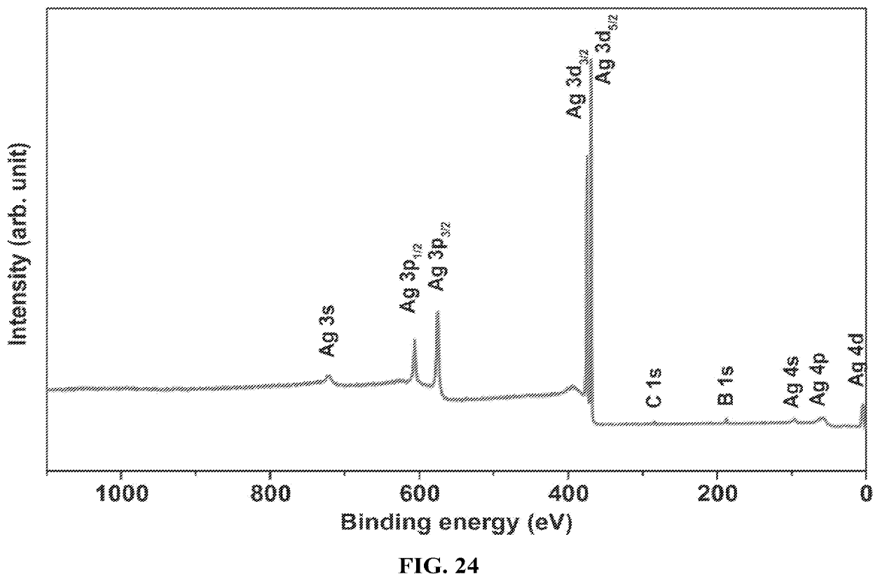

In contrast, the borophane sample exhibits markedly improved chemical and morphological stability in ambient conditions. It should be noted that this sample contains multiple borophane polymorphs (e.g., rect-v_{1/6}-30° borophane, hex-v_{1/6}-30° borophane, square-borophane, and honeycomb-v_{1/5} borophane), thus showing that diverse hydrogen bonding motifs on borophene impart ambient stability. As revealed in panel C of FIG. 4 and FIG. 24, the borophane sample shows no detectable B—O peak in the XPS spectrum after 1 hour of ambient exposure. Similarly, panel D of FIG. 4 reveals the smooth morphology of the borophane sample with no discernible evidence of oxidation as measured by AFM following 1 hour in ambient conditions. The chemical and morphological invariance of the borophane sample persisted after 1 day of ambient exposure (panels E-F of FIG. 4). Only after 1 week of ambient exposure is degradation detected in the borophane sample with the XPS spectrum showing a small B—O peak (panel G of FIG. 4). AFM imaging of this sample reveals that the oxidation initiates at the borophane flake edges as evidenced by the location of the emerging oxide particles (panel H of FIG. 4). With ambient stability on the order of days, borophane provides a sufficiently long time window for most ambient characterization and processing methods.

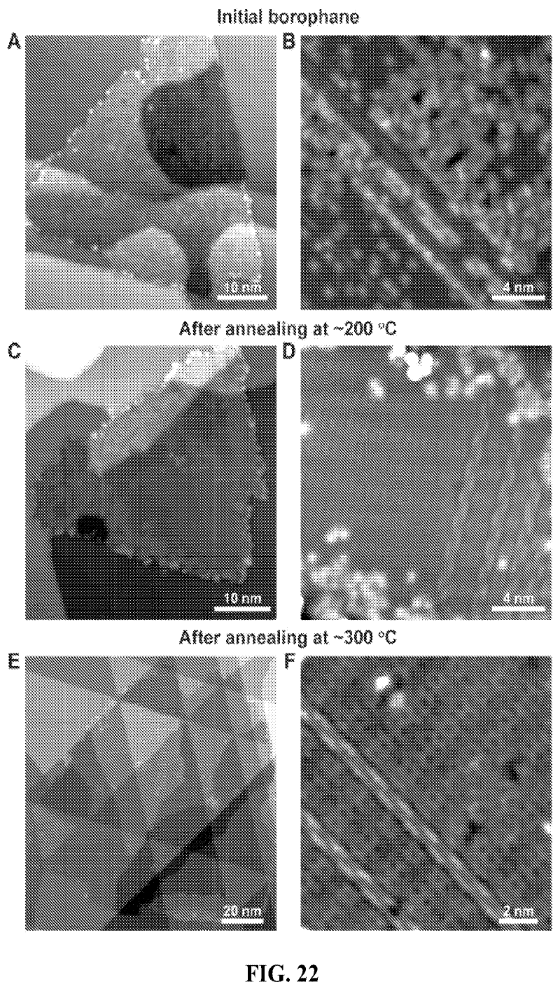

Moreover, similar to the case of hydrogenated graphene, the hydrogenation of borophene is reversible upon thermal annealing. Specifically, borophane samples can be recovered to pristine borophene without apparent degradation after annealing the sample to ˜300° C. (FIG. 22). Consequently, hydrogenation of borophene can be viewed as a reversible passivation scheme in which the hydrogenation can be removed to regain pristine borophene once ambient processing is complete and/or robust encapsulation layers are applied.

### Materials and Methods

Synthesis of Borophane Polymorphs:

The synthesis of borophane polymorphs was achieved by a two-step procedure of boron deposition and subsequent hydrogenation in an ultrahigh vacuum (UHV) chamber (base pressure ˜1.0×10⁻¹⁰ mbar). Boron deposition was conducted by electron-beam evaporation (Focus EFM 3) of a solid boron rod (ESPI metals, 99.9999% purity). Borophene was grown on about 600 nm thick Ag(111) on mica substrates (Princeton Scientific Corp.), which were cleaned via repeated cycles of Ar⁺ sputtering followed by annealing at 550° C. The substrates were held at 400-550° C. during boron deposition, and a flux of 10-15 nA was maintained for 20-30 min for growth of sub-monolayer borophene. Subsequent hydrogenation was conducted by exposing the as-grown borophene sample to atomic hydrogen. The atomic hydrogen was generated by dissociation of molecular hydrogen with a hot tungsten filament held at 1600° C. During hydrogenation, the sample was maintained at room temperature and directly faced the tungsten filament with a distance of ˜10 cm. The chamber pressure during hydrogenation was maintained at 1.0-5.0×10⁻⁶ mbar for 1-20 min.

Scanning Tunneling Microscopy and Spectroscopy:

Scanning tunneling microscopy and spectroscopy (STM/STS) were performed in a Scienta Omicron LT system (base pressure ˜5.0×10⁻¹¹ mbar) at ˜4 K using electrochemically etched Pt/Ir tips. Tip functionalization with CO molecules was obtained by backfilling the STM chamber with 2.0×10⁻⁷ mbar of CO for 30 s, with the STM shroud open to allow adsorption of CO onto the cryogenic sample surface. The adsorbed CO molecules were picked up by the STM tip at low sample bias <10 mV. STS measurements were performed using a lock-in amplifier (Signal Recovery 7270) with an amplitude of 3 mV_{RMS} and a modulation frequency of 822 Hz. For field emission resonance (FER) spectroscopy, dI/dV spectra were recorded in constant current mode, which enables a relatively wide voltage window, resulting in the tip continuously retracting from the sample surface during the measurements. For inelastic electron tunneling spectroscopy (LETS), d²I/dV² spectra were taken with an amplitude of 7 mV_{RMS} and a modulation frequency of 522 Hz. The |dlnI/dz| measurements were performed with a lock-in amplifier (SRS SR850), where an AC output (863 Hz) voltage was added to the z scanner piezo driving signal, causing a 0.3 Å_{RMS} tip position oscillation. Gwyddion software was used for image processing.

Ex Situ Characterization:

X-ray photoelectron spectroscopy (XPS) measurements were acquired with a Thermo Scientific ESCALAB 250Xi system with a monochromated Al Kα X-ray source. The energy resolution was 0.1 eV with a pass energy of 50 eV. All boron spectra were recorded with an average of 100 scans with a 50 ms dwell time. Avantage (Thermo Scientific) software was used for the calibration and fitting of the XPS spectra. Atomic force microscopy (AFM) was performed in ambient conditions with an Asylum Cypher AFM by Oxford Instruments. The AFM images were obtained in tapping mode (NCHR tips, ˜320 kHz, Nanoworld). The relative humidity was between 20% and 50% throughout the study.

Density Functional Theory Calculations:

Density functional theory (DFT) calculations were performed using the plane-wave code Vienna Ab-initio Simulation Package (VASP) with the projector augmented wave (PAW) method. The Perdew-Burke-Ernzerhof (PBE) generalized gradient approximation was used for the exchange-correlation functional. To study the effect of interlayer dispersion forces in the stability of the calculated structures, the dispersion-corrected vdW-optB88 exchange-correlation functional was applied. A cutoff energy of 500 eV and an auto-generated Gamma-centered k-point mesh with 50 k-points per Å⁻¹ were used. The total energy was converged to less than 1 meV with respect to the energy cutoff and k-point sampling. To account for the odd number of valence electrons in the simulation cell, the calculations were performed using spin polarization. The numbers of valence electrons in the pseudopotentials for silver, boron, and hydrogen are 11, 3, and 1, respectively. A minimum vacuum spacing of 18 Å was used for all calculations between the periodic images of the slabs.

The simulated STM images were calculated using the python package Ingrained, which performs computer-vision-based image similarity to match the simulated and experimental STM images. The projected density of states (pDOS) of all structures were calculated using the tetrahedron method with Blöchl corrections. The finite-difference approach was used to calculate the vibrational modes of the proposed rect-v_{1/6}-30° borophane structures, which were initially relaxed with an energy convergence criterion of 10⁻⁸ eV. The dynamical matrix for vibrational modes was calculated by allowing four ionic displacements with a step size of 0.01 Å in each direction for every boron and hydrogen atom in the cell. Local work functions for all structures were calculated from the planar-averaged electrostatic potential profiles, with dipole corrections to account for the dipole moments between the top and bottom surfaces of the slabs.

The silver substrate included seven atomic layers for structure relaxation, pDOS, and work function calculations, and five layers for simulated STM, vibrational modes, and Bader charge analysis. The bottom four layers of the silver substrate were frozen to resemble the bulk silver lattice for all calculations.

Selective Adsorption of Hydrogen on Borophene:

During the initial hydrogenation of borophene (i.e., low dosing condition with 1.0×10⁻⁷ mbar chamber pressure), a preference for H adsorption on certain borophene phases is found. FIG. 5 shows the STM images of low coverage hydrogen adatoms on mixed-phase borophene, which are highlighted as yellow protrusions. The H adatoms are identified according to their size and shape based on a detailed comparison with atomic H adsorbates on graphene. The majority of the adatoms selectively adsorbed on the v_{1/6} phase instead of v_{1/5} phase, as demonstrated by preferential adsorption on v_{1/6} line defects (marked with green arrows in panel B of FIG. 5) and v_{1/6} domains (panel D of FIG. 5).

STM Imaging Hex-v_{1/6} and Rect-v_{1/6}-30° Borophane Structures with Bare and Functionalized Probes:

Hex-v_{1/6} borophane was characterized as a disordered structure with a bare STM tip, as confirmed by the fast Fourier transform (FFT) pattern (panels A-B of FIG. 6). To gain higher spatial resolution, disordered hex-v_{1/6} borophane was imaged with a CO-functionalized STM tip. Compared to the bare-tip image in panel C of FIG. 6, the high-resolution CO-STM image in panel D of FIG. 6 reveals locally ordered hexagonal H patterns. Numerous vacancies and dislocations are present in the hex-v_{1/6} borophane structure, which leads to the disordered morphology when imaged with a bare STM probe. An inserted v_{1/5} line defect is marked with a green arrow in panels C-D of FIG. 6, which also indicates selective H adsorption on the v_{1/6} instead of the v_{1/5} phase. Moreover, the H adsorption initiates from v_{1/6} borophene edges as well as the 60° grain boundaries (GBs), as demonstrated with the low-coverage hex-v_{1/6} borophane case in panels E-F of FIG. 6.

Rect-v_{1/6}-30° borophane was imaged as a parallel striped pattern with 0.50±0.02 nm intervals with a bare STM tip, as shown in panel A of FIG. 7. Intermixed hex-v_{1/6}-30° borophane was also characterized as a disordered structure, consistent with that of hex-v_{1/6} borophane. However, with a CO-functionalized STM tip, the rectangular lattice was clearly resolved on rect-v_{1/6}-30° borophane with a lattice constant of 0.50±0.02 nm by 0.30±0.02 nm.

Predominant Rect-v_{1/6}-30° Borophane Phase:

Although coexisting with some hexagonal H patterns, the rectangular H pattern is the predominant phase with the highest coverage on v_{1/6}-30° borophane as observed in FIG. 8. Unlike hex-v_{1/6}-30° borophane that only has local structural order, rect-v_{1/6}-30° borophane has long-range order. Rect-v_{1/6}-30° borophane shares the same lattice constant as the v_{1/6}-30° borophene template (0.50 nm by 0.30 nm), resulting in a large-area commensurate adsorption structure.

Hydrogen Adsorption Energy Landscapes on v_{1/6}-30° Borophene:

Adsorption energies of H atoms on v_{1/6}-30° borophene were calculated by systematically placing H atoms over an 11×6 grid on the surface of the 5 Å×3 Å unit cell while only allowing H atoms to relax in the z-direction. Panel A of FIG. 9 shows the energy landscape of hydrogen adsorption energies on bare v_{1/6}-30° borophene, where H_{bridge} is found as the most favorable H adsorption site. With the B—H—B ‘banana’ bond formed at the H_{bridge} site, H atoms were continued to be placed on the rect-1H_{bridge} unit cell. The energy landscape of the second H adsorption on the rect-1H_{bridge} structure is shown in panel B of FIG. 9, where Hₜₒₚ is the second most favorable site to form a B—H bond. However, the rect-1Hₜₒₚ is more stable than the rect-1H_{bridge} structure after relaxing the borophene layer. Hence, three structures (i.e., rect-1H_{bridge}, rect-1Hₜₒₚ, and rect-2H) were considered as candidates for rect-v_{1/6}-30° borophane. The total energies and adsorption energies of all structures are provided in Table 1.

Stable Alignment of Rect-v_{1/6}-30° Borophane on Ag(111):

The stable alignment of v_{1/6}-30° borophene on the Ag(111) substrate was determined by calculating the total energy when sliding the 2D borophene layer on a 6×4 grid on the Ag(111) surface used for the H adsorption calculations. Panels A-C of FIG. 10 show the corresponding H-adsorption structures. Because the H adsorption changes the charge distribution within the borophene layer (FIG. 20), the alignment of the borophane layer with the Ag(111) substrate was further investigated. The rect-v_{1/6}-30° borophane structures were also translated similarly as bare borophene on the Ag(111) surface with the resulting total energy landscapes shown in panels D-F of FIG. 10. After translation, the rect-v_{1/6}-30° borophane layer was allowed to slide and fully relax on the Ag(111) substrate to achieve the lowest energy alignment, which resulted in the translated structures: t-rect-1Hₜₒₚ, t-rect-1H_{bridge}, and t-rect-2H. The t-rect-1Hₜₒₚ slides 1.13 Å in the direction of 41° with respect to the x-axis (panel G of FIG. 10), and the t-Rect-1H_{bridge} and t-rect-2H structures slide 1.72 Å along the x-axis (panels H-I of FIG. 10).

To further compare the translated structures with the experimental results, the simulated STM images of t-rect-1Hₜₒₚ, t-rect-1H_{bridge}, and t-rect-2H are shown in FIG. 11. The t-rect-1Hₜₒₚ STM simulation reveals electron densities that originate from the Hₜₒₚ atoms, while the experimental ladder-like patterns are absent. The t-rect-1H_{bridge} structure shows electron densities that originate from the H_{bridge} atoms and the 6-fold coordinated B atoms (Hₜₒₚ site), which are equidistant in a row. For the t-rect-2H structure, although two H atoms are present in its unit cell, only the electron densities from the Hₜₒₚ atoms were revealed in the simulated STM image. None of the three translated structures match the experimental STM images.

The projected density of states (pDOS) of the translated borophane structure (FIG. 14) was also compared with the experimental STS results. Rect-v_{1/6}-30° borophane shows a characteristic peak at ˜1.2 V in the STS spectrum, which is absent in all other borophane polymorphs (FIG. 13). This result is consistent with the higher local density of states (LDOS) at 1.2 eV in the differential tunneling conductance map (FIG. 12). For the translated borophane structure, the experimental state at −1.2 V is not observed in any of the three structures (t-rect-1Hₜₒₚ, t-rect-1H_{bridge}, and t-rect-2H). Instead, a peak at ˜0.93 eV is present for t-rect-2H (FIG. 14), which is different from the peak before translation (rect-2H) at −1.2 eV. The electron densities contributing to the characteristic peaks of rect-2H and t-rect-2H structures are plotted in FIG. 15. The characteristic peak of the rect-2H (1.21-1.25 eV) structure results predominantly from the Hₜₒₚ atoms, while that of the t-rect-2H structure (0.91-0.95 eV) originates from both the Hₜₒₚ and H_{bridge} atoms. From both the STM simulated images and the pDOS calculations, the translated structures are not consistent with experimental results. This discrepancy suggests that edges and defects present experimentally prevent the sliding of borophene on Ag(111) upon H adsorption.

Local Work Function of Rect-v_{1/6}-30° Borophane:

When the Fermi level of the tip exceeds the sample vacuum level, new current channels associated with field emission resonances (FERs) begin to appear, as schematically shown in panel A of FIG. 17. The energies of these resonances depend on the sample local work function (LWF) and the external electric field according to the following equation:

$$e {V}_{n} = ϕ + {( \frac{3 π heE}{2 \sqrt{2 m}} )}^{2 / 3} {n}^{2 / 3} , \qquad ( 1 )$$

where Vₙ is the applied sample bias voltage of the n^{th} resonance (n=1, 2, . . . ), ϕ is the sample LWF, and E is the electric field between the tip and surface.

Following equation (1), the LWF can be estimated by plotting eVₙ−n^{2/3} (n≥3) (panel B of FIG. 17). The lower-order FER levels should be excluded since their electrons are confined close to the surface and strongly affected by the sample surface image potential. The LWF of rect-v_{1/6}-30° borophane is extracted as 4.36±0.09 eV, as shown in panel B of FIG. 17. On the other hand, hex-v_{1/6}-30° borophane possesses a higher LWF of 5.06±0.11 eV, as demonstrated in FIG. 19. The hex-v_{1/6}-30° borophane LWF value is consistent with its first resonance peak at ˜5.0 eV, which is much higher than that of rect-v_{1/6}-30° borophane.

The apparent barrier height (ϕₐₚ) can be extracted from the exponential dependence of the tunneling current (I) on the tip-sample separation (z):

$${ϕ}_{ap} = \frac{{h}^{2}}{8 m} {( \frac{d ln l}{dz} )}^{2} . \qquad ( 2 )$$

From equation (2), ϕₐₚ is directly related to |d ln I/dz|. To better visualize the variations in the LWF between borophane polymorphs, |d ln I/dz| maps were acquired simultaneously with constant-current STM imaging (FIG. 21). The apparent barrier height measurements follow the same qualitative trend as the FER measurements (panel F of FIG. 3), which supports the validity of visualizing LWF spatial variations with |d ln I/dz| maps. The apparent barrier height differences between borophane polymorphs and Ag(111) are shown in panels A-B of FIG. 21. The Ag(111) substrate shows a lower contrast than the v_{1/6}-30° borophane domain, indicating a lower work function. The contrast within the v_{1/6}-30° borophane is inhomogeneous, which results from the intermixing of rectangular and hexagonal v_{1/6}-30° borophane phases. A direct comparison between the rectangular and hexagonal v_{1/6}-30° borophane polymorphs is shown in panels D-C of FIG. 21, where rect-v_{1/6}-30° borophane shows a lower contrast than hex-v_{1/6}-30° borophane. This result agrees well with FER measurements and DFT calculations.

Local Potential Distribution of the Rect-1Hₜₒₚ Structure:

The side view of the local potential distribution of the rect-1Hₜₒₚ structure along the plane of H atoms is shown in FIG. 18. The vertical green and blue lines indicate the lateral locations of the H_{bridge} and Hₜₒₚ sites, respectively (only one H atom is present at the Hₜₒₚ site). The potential profiles versus height (in units of Å) along the green and blue lines are shown in the right panel of FIG. 18. In contrast to the sharp rise in potential profile above the Hₜₒₚ site of the rect-2H surface (panel B of FIG. 3), the potential above the Hₜₒₚ site of rect-1Hₜₒₚ gradually converges to the vacuum level. Therefore, the corrugated isosurface of the rect-2H structure is not observed on the rect-1Hₜₒₚ structure.

Bader Analysis of Rect-v_{1/6}-30° Borophane:

Bader analysis was performed on rect-v_{1/6}-30° borophane structures to investigate the charge transfer between the species. FIG. 20 shows the estimated net charge on the B and H atoms for bare v_{1/6}-30° borophene and the three proposed rect-v_{1/6}-30° borophane structures (i.e., rect-1H_{bridge}, rect-1Hₜₒₚ, and rect-2H). As shown in panel A of FIG. 20, v_{1/6}-30° borophene has alternating rows of positively and negatively charged boron atoms with H atoms preferring to adsorb on top of the positively charged B atoms and receiving more electrons from B atoms. The charge distributions on the Hₜₒₚ sites remain similar for the rect-1Hₜₒₚ and rect-2H structures (panels C-D of FIG. 20). In contrast, for the H_{bridge} sites, the H_{bridge} atoms in the rect-2H are more negatively charged (−0.71 |e|) than in rect-1H_{bridge} (−0.41|e|), as shown in panels B-D of FIG. 20. Based on the charge transfer between the H adatoms and borophene, borophane can be considered to be a 2D boron hydride.

Thermal Stability of Borophane:

In order to test thermal stability, borophane samples were annealed in UHV. After annealing at 200° C. for 1 hour, hydrogen desorption was observed from borophane, as shown in panels C-D of FIG. 22. The H adatoms were fully desorbed after annealing at 300° C. for 1 hour (panels E-F of FIG. 22). This result is consistent with previously reported hydrogen boride sheets, where hydrogen (H₂) was detected as the major desorption species. The STM image of borophane after thermal annealing (panels E-F of FIG. 22) reveals an intact lattice of borophene without apparent degradation, indicating fully reversible hydrogenation analogous to graphane.

### CONCLUSION

In summary, a diverse set of borophane polymorphs have been synthesized by exposing borophene to atomic hydrogen in UHV. Among these borophane polymorphs, rect-v_{1/6}-30° borophane showed the most highly ordered domains, thus facilitating further interrogation of its atomic and electronic structure. Through atomically resolved STM, STS, LETS, and DFT calculations, rect-v_{1/6}-30° borophane is found to possess the rect-2H structure, which includes a combination of 2c2e B—H and 3c2e B—H—B bonds. Furthermore, FER spectroscopy, apparent barrier height imaging, and DFT revealed that hydrogenation lowers the LWF of v_{1/6}-30° borophene. FER spectroscopy also showed a splitting of the first FER peak of rect-v_{1/6}-30° borophane, which is consistent with the surface potential corrugation resulting from the combination of 2c2e B—H and 3c2e B—H—B bonds. Chemically, hydrogenation acts as a robust passivation scheme for borophene with multiple borophane polymorphs suppressing oxidation in ambient conditions for timescales on the order of days. Since this hydrogenation can be reversibly removed through thermal annealing, borophane can be returned to pristine borophene following ambient processing, thus presenting significant flexibility in borophene sample preparation. Overall, this work reveals the richness of borophane chemistry, which is likely to inspire and motivate future exploration of covalently modified borophene polymorphs.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

Some references, which may include patents, patent applications, and various publications, are cited and discussed in the description of this invention. The citation and/or discussion of such references is provided merely to clarify the description of the invention and is not an admission that any such reference is “prior art” to the invention described herein. All references cited and discussed in this specification are incorporated herein by reference in their entireties and to the same extent as if each reference was individually incorporated by reference.

### LIST OF REFERENCES

[1]. A. J. Mannix et al., Synthesis of borophenes: Anisotropic, two-dimensional boron polymorphs. Science 350, 1513-1516 (2015).
[2]. A. J. Mannix et al., Borophene as a prototype for synthetic 2D materials development. Nat. Nanotechnol. 13, 444-450 (2018).
[3]. E. S. Penev et al., Can two-dimensional boron superconduct? Nano Lett. 16, 2522-2526 (2016).
[4]. B. Feng et al., Experimental realization of two-dimensional boron sheets. Nat. Chem. 8, 563-568 (2016).
[5]. J. A. Dagata et al., Modification of hydrogen-passivated silicon by a scanning tunneling microscope operating in air. Appl. Phys. Lett. 56, 2001-2003 (1990).
[6]. J. W. Lyding et al., Nanoscale patterning and oxidation of H-passivated Si(100)-2×1 surfaces with an ultrahigh vacuum scanning tunneling microscope. Appl. Phys. Lett. 64, 2010-2012 (1994).
[7]. C. R. Ryder et al., Covalent functionalization and passivation of exfoliated black phosphorus via aryl diazonium chemistry. Nat. Chem. 8, 597-602 (2016).
[8]. L.-C. Xu, et al., Hydrogenated borophene as a stable two-dimensional Dirac material with an ultrahigh Fermi velocity. Phys. Chem. Chem. Phys. 18, 27284-27289 (2016).
[9]. M. Pumera, C. H. A. Wong, Graphane and hydrogenated graphene. Chem. Soc. Rev. 42, 5987-5995 (2013).
[10]. R. Balog et al., Bandgap opening in graphene induced by patterned hydrogen adsorption. Nat. Mater. 9, 315-319 (2010).
[11]. A. A. Kistanov et al., Exploring the charge localization and band gap opening of borophene: a first-principles study. Nanoscale 10, 1403-1410 (2018).
[12]. Z.-Q. Wang et al., Band gap opening in 8-Pmmn borophene by hydrogenation. ACS Appl. Electron. Mater. 1, 667-674 (2019).
[13]. D. Li et al., Stretch-driven increase in ultrahigh thermal conductance of hydrogenated borophene and dimensionality crossover in phonon transmission. Adv. Funct. Mater. 28, 1801685 (2018).
[14]. H. Nishino et al., Formation and characterization of hydrogen boride sheets derived from MgB₂ by cation exchange. J. Am. Chem. Soc. 139, 13761-13769 (2017).
[15]. C. Hou et al., Ultrastable crystalline semiconducting hydrogenated borophene. Angew. Chem. Int. Ed. 59, 10819-10825 (2020).
[16]. X. Liu et al., Geometric imaging of borophene polymorphs with functionalized probes. Nat. Commun. 10, 1642 (2019).
[17]. R. Balog et al., Atomic hydrogen adsorbate structures on graphene. J. Am. Chem. Soc. 131, 8744-8745 (2009).
[18]. X. Liu et al., Intermixing and periodic self-assembly of borophene line defects. Nat. Mater. 17, 783-788 (2018).
[19]. Z. Zhang et al., Substrate-induced nanoscale undulations of borophene on silver. Nano Lett. 16, 6622-6627 (2016).
[20]. P. Laszlo, A diborane story. Angew. Chem. Int. Ed. 39, 2071-2072 (2000).
[21]. W. N. Lipscomb, The boranes and their relatives. Science 196, 1047-1055 (1977).
[22]. G. Binnig et al., Tunneling spectroscopy and inverse photoemission: Image and field states. Phys. Rev. Lett. 55, 991-994 (1985).
[23]. R. S. Becker et al., Electron interferometry at crystal surfaces. Phys. Rev. Lett. 55, 987-990 (1985).
[24]. J. Martinez-Blanco, S. Folsch, Light emission from Ag(111) driven by inelastic tunneling in the field emission regime. J. Phys. Condens. Matter. 27, 255008 (2015).
[25]. J. Martínez-Blanco et al., Energy splitting of image states induced by the surface potential corrugation of InAs(111) A. Phys. Rev. B 92, 115444 (2015).
[26]. C. W. Ong et al., X-ray photoemission spectroscopy of nonmetallic materials: Electronic structures of boron and BₓO_{y}. J. Appl. Phys. 95, 3527-3534 (2004).
[27]. D. C. Elias et al., Control of graphene's properties by reversible hydrogenation: evidence for graphane. Science 323, 610-613 (2009).
[28]. G. Kresse, J. Furthmüller, Efficiency of ab-initio total energy calculations for metals and semiconductors using a plane-wave basis set. Comput. Mater. Sci. 6, 15-50 (1996).
[29]. G. Kresse, J. Furthmüller, Efficient iterative schemes for ab initio total-energy calculations using a plane-wave basis set. Phys. Rev. B 54, 11169-11186 (1996).
[30]. P. E. Blöchl, Projector augmented-wave method. Phys. Rev. B 50, 17953-17979 (1994).
[31]. G. Kresse, D. Joubert, From ultrasoft pseudopotentials to the projector augmented-wave method. Phys. Rev. B 59, 1758-1775 (1999).
[32]. J. P. Perdew, K. Burke, M. Ernzerhof, Generalized gradient approximation made simple. Phys. Rev. Lett. 77, 3865-3868 (1996).
[33]. M. Dion et al., Van der Waals density functional for general geometries. Phys. Rev. Lett. 92, 246401 (2004).
[34]. P. E. Blöch et al., Improved tetrahedron method for Brillouin-zone integrations. Phys. Rev. B 49, 16223-16233 (1994).
[35]. O. Y. Kolesnychenko et al., Field-emission resonance measurements with mechanically controlled break junctions. Physica B Condens. Matter 291, 246-255 (2000).
[36]. Y. Hasegawa et al., Elemental contrast of local work function studied by scanning tunneling microscopy. Surf Sci. 386, 328-334 (1997).
[37]. W. Tang, E. Sanville, G. Henkelman, A grid-based Bader analysis algorithm without lattice bias. J. Phys. Condens. Matter. 21, 084204 (2009).
[38]. J. W. Lyding and K. Hess, Deuterium-treated semiconductor devices (1999), U.S. Pat. No. 5,872,387.
[39]. J. W. Lyding et al., Deuterium treatment of semiconductor device (2004), U.S. Pat. No. 6,833,306.
[40]. G. B. Basim et al., Hydrogen passivation of integrated circuits (2015), U.S. Pat. No. 9,218,981.
[41]. R. Kawamura et al., Nat. Commun. 10, 4880 (2019).
[42]. B. Feng et al., Phys. Rev. B 94, 041408 (2016).

1. A method of synthesizing borophane polymorphs, comprising:
growing borophene on a substrate in an ultrahigh vacuum (UHV) chamber; and
performing hydrogenation of the borophene in situ to obtain borophane having a diverse set of borophane polymorphs.

2. The method of claim 1, wherein the UHV chamber has a base pressure of about 1.0×10⁻¹⁰ mbar during the borophene growth.

3. The method of claim 1, wherein the substrate comprises a substrate having a metal film formed of Ag, Au, Cu, Al, or Ir.

4. The method of claim 3, wherein the substrate comprises an atomically clean Ag(111) substrate having about 480-720 nm thick Ag(111) on a mica substrate.

5. The method of claim 4, wherein the substrate is obtained by cleaning the mica substrate via repeated cycles of Ar⁺ sputtering followed by annealing at about 450-550° C.

6. The method of claim 1, wherein said growing the borophene on the substrate comprises depositing boron on the substrate at a substrate temperature.

7. The method of claim 6, wherein said depositing the boron is performed by electron-beam evaporation of a solid boron rod, or high temperature effusion of the solid boron rod in a high temperature effusion cell.

8. The method of claim 7, wherein the solid boron rod has a purity of about 99.999-99.99999% boron.

9. The method of claim 6, wherein the substrate temperature is at about 320-660° C. during boron deposition.

10. The method of claim 6, wherein the borophene grown on the substrate has a dominant borophene polymorph determined by the substrate temperature.

11. The method of claim 1, wherein said hydrogenation is performed in situ by exposing the borophene to atomic hydrogen.

12. The method of claim 11, wherein the atomic hydrogen is generated by dissociation of molecular hydrogen with a tungsten filament, a platinum filament, an iridium filament, or platinum/iridium filament, or by a hydrogen atom beam source that thermally crack molecular hydrogen into atomic hydrogen.

13. The method of claim 12, wherein during hydrogenation, the borophene is maintained at room temperature and directly faced the tungsten filament with a distance of about 8-12 cm.

14. The method of claim 11, wherein the chamber pressure during hydrogenation is maintained at about 1.0×10⁻⁷-5.0×10⁻⁶ mbar for about 1-20 min.

15. The method of claim 1, wherein the diverse set of borophane polymorphs comprises at least eight borophane polymorphs.

16. The method of claim 15, wherein the diverse set of borophane polymorphs comprises:
v_{1/5} borophane with square H and honeycomb H patterns;
v_{1/5}-30° borophane with staggered rectangular H and zigzag H patterns;
v_{1/6} borophane with hexagonal H and disordered rectangular H patterns; and
v_{1/6}-30° borophane with hexagonal H and rectangular H patterns, wherein H represents hydrogen atoms.

17. The method of claim 16, wherein the v_{1/6}-30° borophane with the rectangular H pattern (rect-v_{1/6}-30° borophane) comprises two-center-two-electron (2c2e) boron-hydrogen (B—H) bonds and three-center-two-electron (3c2e) boron-hydrogen-boron (B—H—B) bonds.

18. The method of claim 17, wherein the rect-v_{1/6}-30° borophane has a lower work function than v_{1/6}-30° borophene.

19. The method of claim 1, wherein the borophane polymorphs have tunable stoichiometric ratios of boron and hydrogen.

20. The method of claim 1, wherein the borophane polymorphs have negligible oxidation for multiple days following ambient exposure.

21. The method of claim 1, wherein the borophane polymorphs are metallic with modified local work functions compared to pristine borophene.

22. The method of claim 1, wherein the borophane polymorphs are reversibly returnable to pristine borophene via thermal desorption of hydrogen.

23. A method of synthesizing borophane polymorphs, comprising:
hydrogenating borophene with atomic hydrogen in ultrahigh vacuum (UHV).

24. The method of claim 23, wherein the borophene is grown on a substrate in the UHV by elemental boron evaporation.

25. The method of claim 24, wherein the substrate comprises a substrate having a metal film formed of Ag, Au, Cu, Al, or Ir.

26. The method of claim 23, wherein the borophene grown on the substrate has a dominant borophene polymorph determined by a substrate temperature of the substrate.

27. The method of claim 26, wherein the substrate temperature is at about 320-660° C. during boron deposition.

28. The method of claim 23, wherein said hydrogenating the borophene is performed by exposing borophene to atomic hydrogen.

29. The method of claim 28, wherein the atomic hydrogen is generated by dissociation of molecular hydrogen with a tungsten filament, a platinum filament, an iridium filament, or platinum/iridium filament, or by a hydrogen atom beam source that thermally crack molecular hydrogen into atomic hydrogen.

30. The borophane polymorphs, being synthesized according to the method of claim 1.

31. Borophane, comprising:
hydrogenated borophene having a diverse set of borophane polymorphs.

32. The borophane of claim 31, wherein the diverse set of borophane polymorphs comprises:
v_{1/5} borophane with square H and honeycomb H patterns;
v_{1/5}-30° borophane with staggered rectangular H and zigzag H patterns;
v_{1/6} borophane with hexagonal H and disordered rectangular H patterns; and
v_{1/6}-30° borophane with hexagonal H and rectangular H patterns, wherein H represents hydrogen atoms.

33. The borophane of claim 32, wherein the v_{1/6}-30° borophane with the rectangular H pattern (rect-v_{1/6}-30° borophane) comprises two-center-two-electron (2c2e) boron-hydrogen (B—H) bonds and three-center-two-electron (3c2e) boron-hydrogen-boron (B—H—B) bonds.

34. The borophane of claim 33, wherein the rect-v_{1/6}-30° borophane has a lower work function than v_{1/6}-30° borophene.

35. The borophane of claim 31, wherein the borophane polymorphs have tunable stoichiometric ratios of boron and hydrogen.

36. The borophane of claim 31, wherein the borophane polymorphs have negligible oxidation for multiple days following ambient exposure.

37. The borophane of claim 31, being metallic with modified local work functions compared to pristine borophene.

38. The borophane of claim 31, being reversibly returnable to pristine borophene via thermal desorption of hydrogen.
